(19) United States
(12) Patent Application Publication
(10) Pub. No.: US 2024/0289163 A1
(43) Pub. Date: Aug. 29, 2024

(54) DATA COMPRESSION SYSTEM, DATA COMPRESSION METHOD, AND DATA COMPRESSION PROGRAM

(71) Applicant: Hitachi, Ltd., Tokyo (JP)

(72) Inventors: Hiroaki AKUTSU, Tokyo (JP); Ko ARAI, Tokyo (JP); Takahiro NARUKO, Tokyo (JP)

(21) Appl. No.: 18/590,674

(22) Filed: Feb. 28, 2024

(30) Foreign Application Priority Data
Feb. 28, 2023 (JP) 2023-029527

(51) Int. Cl. G06F 9/48; G06F 9/52

(52) U.S. Cl. CPC G06F 9/4806; G06F 9/52

(57) ABSTRACT

In a computer that compresses data, a compressor that divides the compression target data into a plurality of pieces of partial data, and performs compression processing on each piece of the partial data in parallel, the compressor including a probability calculation unit that includes a neural network and calculates an appearance probability for each predetermined data unit of the partial data, and an entropy coding unit that outputs a coded bit string that is an entropy-coded bit string based on the data unit and the appearance probability for each data unit.

### BACKGROUND OF THE INVENTION

### 1. Field of the Invention

The present invention relates to a technology for compressing data.

### 2. Description of Related Art

With the advancement of internet of things (IoT), data generation amount increased significantly, and data storage amount in hybrid clouds increased. Although storage costs are decreasing, it is not enough to cover growth in data volume.

Therefore, it is important to reduce the data volume stored in a storage.

As a related technology, for example, JP2019-95913A discloses a technology that can reduce data volume even when data is unsuitable for compression.

However, although the data volume can be reduced through compression processing, there is a problem that the compression processing takes a long time. When the compression processing takes a long time as such, there is a concern that the cost of computing resources will increase and other processing will be affected.

### SUMMARY OF THE INVENTION

The present invention was made in view of the above circumstances, and the purpose thereof is to provide a technology that can improve a processing speed of compression processing.

To achieve the above object, according to an aspect, there is provided a data compression system that compresses data, the system including: a division unit that divides compression target data into a plurality of pieces of partial data; and a plurality of compression processing units that perform compression processing on each piece of the partial data in parallel, in which the compression processing unit includes a probability calculation unit that includes a neural network and calculates an appearance probability for each predetermined data unit of the partial data, and an entropy coding unit that outputs a coded bit string that is an entropy-coded bit string based on the data unit and the appearance probability for each of the data units.

According to the invention, a processing speed of compression processing can be improved.

### BRIEF DESCRIPTION OF THE DRAWINGS

FIG. 1 is an overall configuration diagram of a computer system according to a first embodiment;

FIG. 2 is a configuration diagram of an address mapping table according to the first embodiment;

FIG. 3 is a configuration diagram of block data storage information according to the first embodiment;

FIG. 4 is a configuration diagram of history information according to the first embodiment;

FIG. 5 is a diagram for describing an overview of backup processing and restoration processing in the computer system according to the first embodiment;

FIG. 6 is a diagram for describing a compressor according to the first embodiment;

FIG. 7 is a diagram for describing a decompressor according to the first embodiment;

FIG. 8 is a flowchart of compression processing by the compressor according to the first embodiment;

FIG. 9 is a flowchart of decompression processing by the decompressor according to the first embodiment;

FIG. 10 is a flowchart of the backup processing according to the first embodiment;

FIG. 11 is a flowchart of the restoration processing according to the first embodiment;

FIG. 12 is a diagram for describing estimation model processing according to the first embodiment;

FIG. 13 is a diagram for describing a data flow of the estimation model processing and mixer model processing according to the first embodiment;

FIG. 14 is a diagram for describing an algorithm of the estimation model processing according to the first embodiment;

FIG. 15 is a diagram for describing the estimation model processing using history information according to the first embodiment;

FIG. 16 is a diagram for describing memory model processing using the history information according to the first embodiment;

FIG. 17 is a diagram for describing the memory model processing using an exponential moving average according to the first embodiment;

FIG. 18 is a diagram for describing a computer system according to a modification example;

FIG. 19 is a diagram for describing a compressor of a computer system according to a second embodiment; and

FIG. 20 is a diagram for describing a decompressor of the computer system according to the second embodiment.

### DESCRIPTION OF EMBODIMENTS

Embodiments will be described with reference to the drawings. The embodiments described below do not limit the invention according to the range of claims, and it is not necessary that all of the elements and combinations described in the embodiments are essential to the solution means of the invention.

In the following description, information may be described in an expression of “AAA table”, but information may be expressed by any data structure. In other words, to indicate that information does not depend on a data structure, “AAA table” can be called “AAA information”.

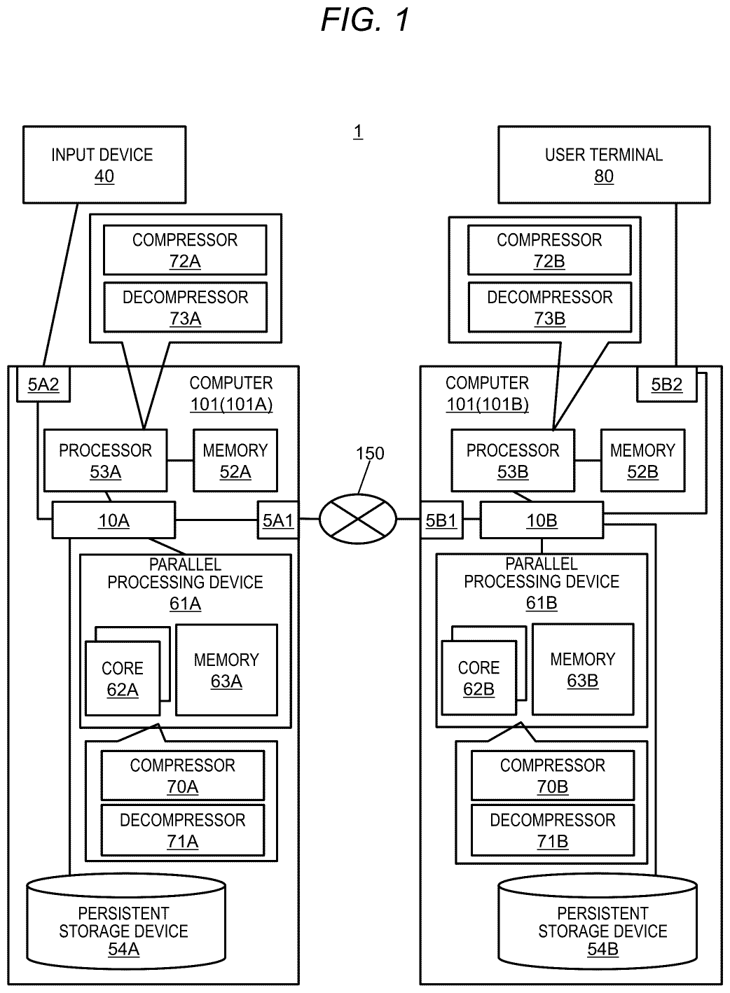

FIG. 1 is an overall configuration diagram of a computer system according to a first embodiment.

A computer system 1 includes an input device 40, a user terminal 80, a computer 101A, and a computer 101B. The computers 101A and 101B are each an example of a data compression system. Note that the computer system 1 can also be referred to as an example of a data compression system. The computer 101A and the computer 101B are connected to each other via a network 150. The network 150 is, for example, a communication channel such as a wired local area network (LAN), a wireless LAN, a wide area network (WAN), or a dedicated line. The computer 101A is connected to the input device 40. The computer 101B is connected to the user terminal 80. Note that the computer 101A and the computer 101B may be virtual computing resources (for example, a virtual machine, a container and the like) in a cloud environment.

The input device 40 is configured with a computer such as a personal computer (PC), and receives input from a user and executes various processing using data. The input device 40 stores data used for processing in the computer 101A, and acquires data from the computer 101A. Note that the input device 40 may be a virtual computing resource (for example, a virtual machine, a container and the like) in a cloud environment.

The user terminal 80 is, for example, configured with a computer such as a PC, and receives instructions from the user to perform settings or the like for the computer 101B. Note that the user terminal 80 may be a virtual computing resource (for example, a virtual machine, a container and the like) in a cloud environment.

The computer 101A stores and manages data used by the input device 40. The computer 101A performs processing for backing up data to the computer 101B and processing for restoring data from the computer 101B. The computer 101A is configured with a computer such as a PC or a server device, and includes a processor 53A, a memory 52A, interfaces (IF) 5A1 and 5A2, a parallel processing device 61A, a persistent storage device 54A, and a bus 10A that connects the units to each other.

The IFs 5A1 and 5A2 are interfaces such as wired LAN cards and wireless LAN cards, and communicate with other devices via the network 150 or communication lines.

The processor 53A executes various processing according to programs stored in the memory 52A. The processor 53A configures a compressor 72A and a decompressor 73A by executing the programs. The processor 53A configures a first block corresponding guarantee code creation unit and a second block corresponding guarantee code creation unit by executing the programs. The compressor 72A performs, for example, compression processing on data. An algorithm for compression processing by the compressor 72A may be gzip, Lempel-Ziv-Markov chain-algorithm (LZMA), or the like. The decompressor 73A decompresses the compressed data. An algorithm for decompression processing by the decompressor 73A may be an algorithm corresponding to the compression processing by the compressor 72A.

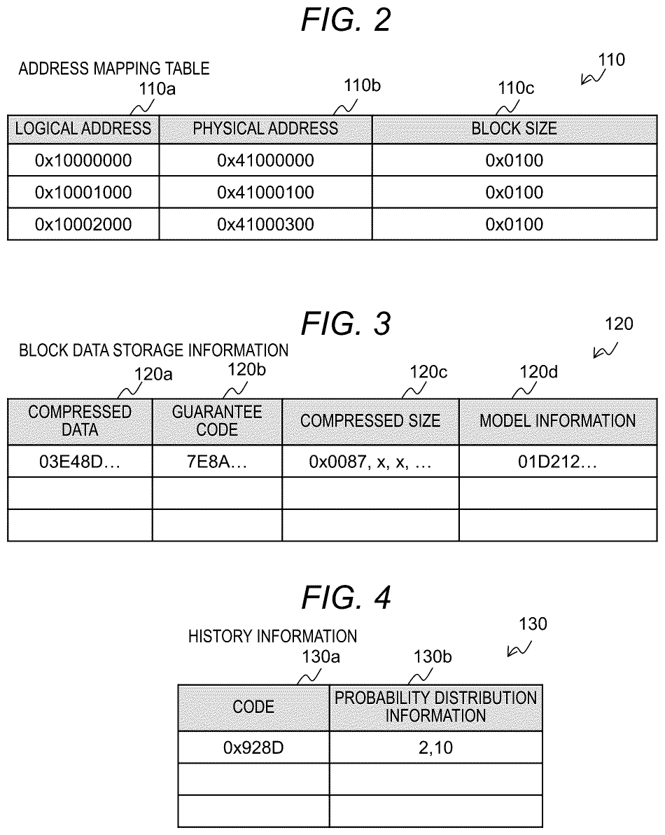

The memory 52A is, for example, a random access memory (RAM), and stores programs executed by the processor 53A and necessary information. In the present embodiment, the memory 52A stores, for example, an address mapping table 110 (refer to FIG. 2).

The persistent storage device 54A is, for example, a hard disk or a flash memory, and stores programs read to the memory 52A for execution by the processor 53A and various data used by the processor 53A. In the present embodiment, the persistent storage device 54A stores a data compression program as a program, and stores block data storage information 120 (refer to FIG. 3) and the address mapping table 110 (refer to FIG. 2) as data. Note that, instead of or in addition to the persistent storage device 54A, a storage on a cloud connected via a network may be used. Note that the persistent storage device 54A and the storage on the cloud may be configured with block storage, file storage, object storage, database, and the like.

The parallel processing device 61A is, for example, a device that can execute processing in parallel, such as a graphics processing unit (GPU), an application specific integrated circuit (ASIC), a field programmable gate array (FPGA), or a multi-core central processing unit (CPU), and includes a plurality of cores 62A and a memory 63A. The core 62A executes processing according to programs stored in the memory 63A. The memory 63A is an example of a storage unit, and stores programs executed by the core 62A and data used by the core 62A. The memory 63A stores, for example, history information 130 (refer to FIG. 4). The plurality of cores 62A can execute various processing in parallel using the memory 63A. In the present embodiment, the parallel processing device 61A configures a compressor 70A and a decompressor 71A by executing programs. In the present embodiment, compression by the compressor 70A is capable of higher compression than compression by the compressor 72A.

The computer 101B stores and manages data managed by the computer 101A. The computer 101B is configured with a computer such as a PC or a server device, and includes a processor 53B, a memory 52B, IFs 5B1 and 5B2, a parallel processing device 61B, a persistent storage device 54B, and a bus 10B that connects the units to each other. The processor 53B configures a compressor 72B and a decompressor 73B as an example of a decompression unit. The parallel processing device 61B includes a plurality of cores 62B and a memory 63B, and configures a compressor 70B and a decompressor 71B. Each configuration of the computer 101B is similar to each configuration of the computer 101A, which has the same number in the first half of the reference numeral. Note that the configurations of the computer 101A and the computer 101B are not limited to those described above, and some of the configurations may not be provided depending on processing to be executed.

Next, the address mapping table 110 will be described.

FIG. 2 is a configuration diagram of an address mapping table according to the first embodiment.

The address mapping table 110 is a table that manages physical addresses corresponding to logical addresses which are storage destinations of data, and stores entries for each area (for example, block) of a predetermined size. An entry in the address mapping table 110 includes fields of a logical address 110a, a physical address 110b, and a block size 110c. The logical address 110a stores a logical address indicating an area corresponding to the entry. The physical address 110b stores a physical address corresponding to the area corresponding to the entry. The block size 110c stores a block size of the area corresponding to the entry.

Next, the block data storage information 120 will be described.

FIG. 3 is a configuration diagram of the block data storage information according to the first embodiment.

The block data storage information 120 is information for managing block data, and includes an entry for each piece of block data. The entry of the block data storage information 120 includes fields of compressed data 120a, a guarantee code 120b, and a compressed size 120c. The compressed data 120a stores compressed data after the block data is compressed. The guarantee code 120b stores a guarantee code for the block data. The compressed size 120c stores a data size of the compressed data. The compression target data is compressed by dividing the data into a plurality of pieces of partial data. Thus, each piece of partial data has a compressed size, and partial recompression and decompression can be performed without decoding the partial data that is not included in the data location to be partially recompressed or decompressed. Model information 120d stores a fully learned model (a model that becomes an initial state of an estimation model or a mixer model). Alternatively, by storing reference information of other corresponding models (models corresponding to other block data that was already learned), the data volume in the block data storage information may be reduced.

Next, the history information 130 will be described.

FIG. 4 is a configuration diagram of history information according to the first embodiment.

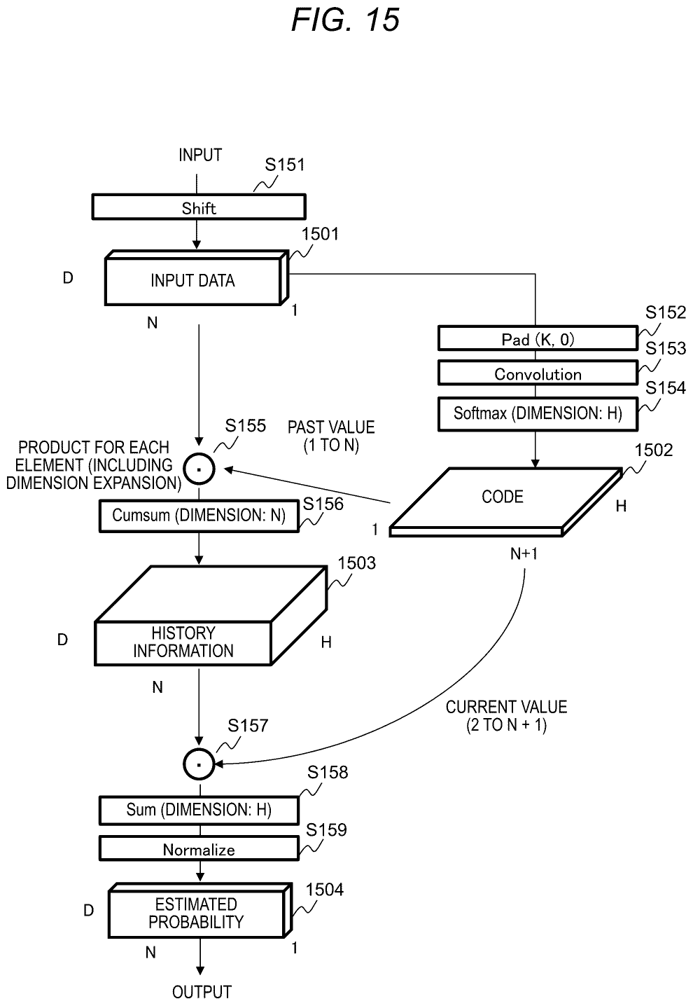

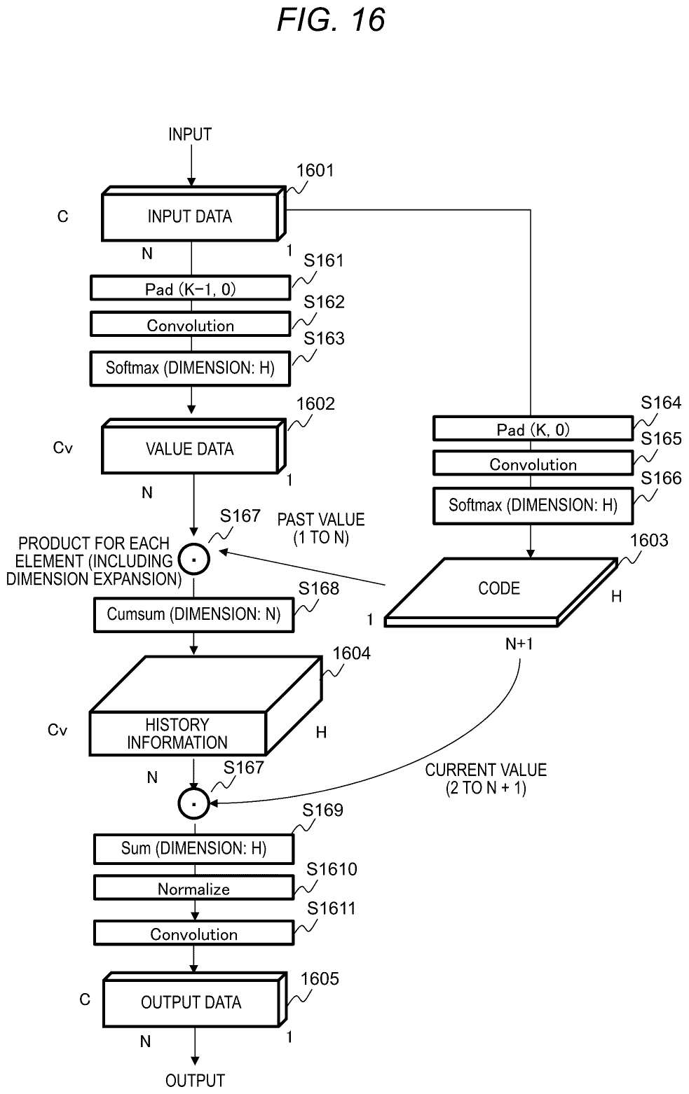

The history information 130 is information that manages a probability distribution corresponding to data used when calculating an appearance probability for a data unit (data used during calculation), and includes an entry for each piece of data used at the time of calculation. The entry of the history information 130 includes fields of a code 130a and probability distribution information 130b. The code 130a stores a predetermined code (identification information) regarding the data used during calculation that corresponds to the entry. The code may be a hash value for data used during calculation or locality sensitive hashing (LSH). A learning type LSH shown in FIGS. 15 and 16, which will be described later, may be used. The probability distribution information 130b stores information regarding a probability distribution calculated using data used during calculation corresponding to the entry. The information regarding the probability distribution may be an appearance frequency of a target data unit or a learning code based on deep neural network (DNN). The history information 130 is stored, for example, when the core 62B executes a program. The function of the core 62B corresponds to a history management unit. An example of a method of generating and using the history information 130 will be described with reference to FIG. 15, which will be described later.

Next, an overview of backup processing and restoration processing in the computer system 1 will be described.

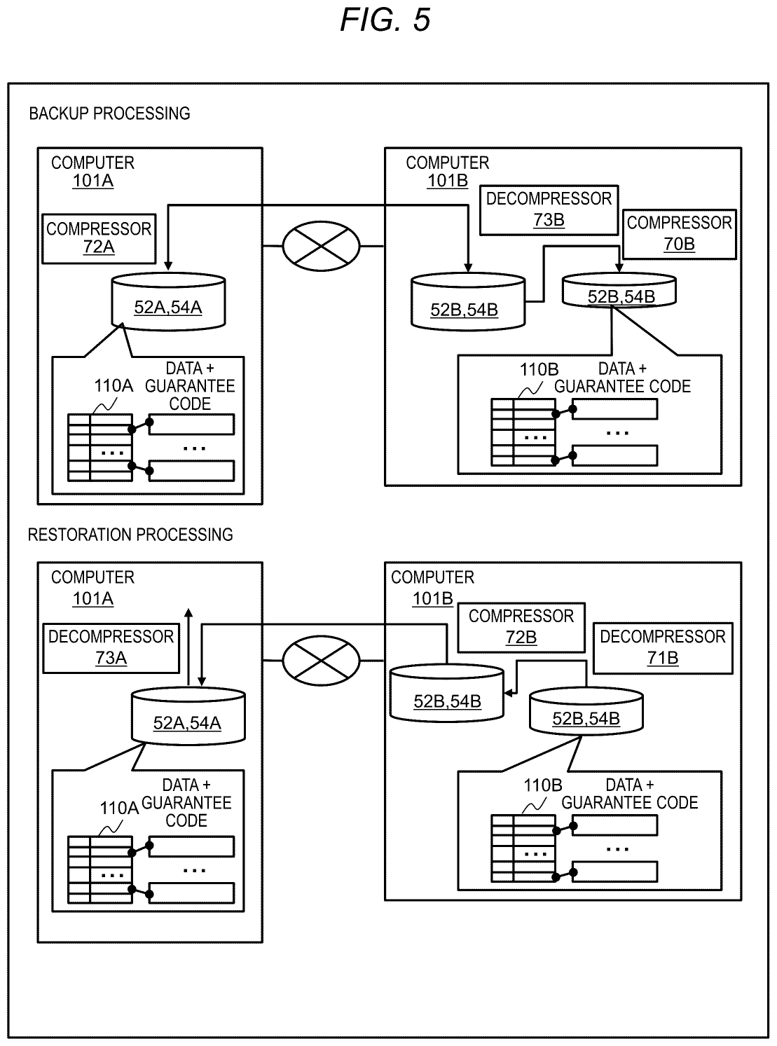

FIG. 5 is a diagram for describing an overview of the backup processing and the restoration processing in the computer system according to the first embodiment.

First, the backup processing will be described. It will be described that, in the backup processing, backup target data is compressed by the compressor 72A of the computer 101A, a guarantee code is created and associated using a predetermined block size (first size) as a unit, and the backup target data is stored in the memory 52A or the persistent storage device 54A.

The computer 101A refers to an address mapping table 110A, specifies the storage location of the backup target data in the memory 52A or the persistent storage device 54A, acquires the backup target data and the guarantee code, and transmits the acquired backup target data and the guarantee code to the computer 101B, which is the backup destination.

The computer 101B stores the received backup target data and the guarantee code in the memory 52B or the persistent storage device 54B, and performs the decompression processing on the backup target data using the decompressor 73B. In the decompression processing, the guarantee code is used to detect and correct errors in the backup target data. Next, the compressor 70B compresses the decompressed backup target data, creates a guarantee code using blocks of a predetermined block size (second size) as a unit, stores the created guarantee code in the memory 52B or the persistent storage device 54B, and registers the storage destination in an address mapping table 110B. However, for partial updating (compressing only a part to be updated without decompressing an entire block), for example, a method may be adopted in which a guarantee code that can be partially updated, such as an XOR parity, is used in units of blocks. Alternatively, a guarantee code may be created for each piece of partial data to support partial updates.

According to the backup processing, the backup target data can be saved in a highly compressed state by the compressor 70B. When the second size is set to be larger than the first size and the guarantee code is created using the second size as a unit of data, the overall data volume can be reduced. Note that the decompression processing by the decompressor 73B of the computer 101B may be executed by the decompressor 73A of the computer 101A, and the decompressed data may be transmitted to the computer 101B.

Next, the restoration processing will be described. In the restoration processing, a case will be described in which the computer 101B is instructed by the computer 101A to use data that was backed up in the backup processing as restoration target data. First, the decompressor 71B of the computer 101B refers to the address mapping table 110B, specifies the storage location of the backup target data in the memory 52B or the persistent storage device 54B, acquires the restoration target data and the guarantee code, and performs the decompression processing. In the decompression processing, the guarantee code is used to detect and correct errors in the restoration target data.

Next, the compressor 72B compresses the decompressed restoration target data using an algorithm that can be decompressed by the decompressor 73A of the computer 101A, creates a guarantee code using a first size as a unit, stores the created guarantee code in the memory 52B or the persistent storage device 54B, and transmits the compressed restoration target data and the guarantee code to the computer 101A which is the restoration destination.

The computer 101A stores the received restoration target data and guarantee code in the memory 52A or the persistent storage device 54A, and registers the storage destination in the address mapping table 110A. Next, the decompressor 73A performs decompression processing on the restoration target data. In the decompression processing, the guarantee code is used to detect and correct errors in the restoration target data. Accordingly, the computer 101A can use the restoration target data.

Next, the configuration and processing of the compressor 70 (70A, 70B) will be described.

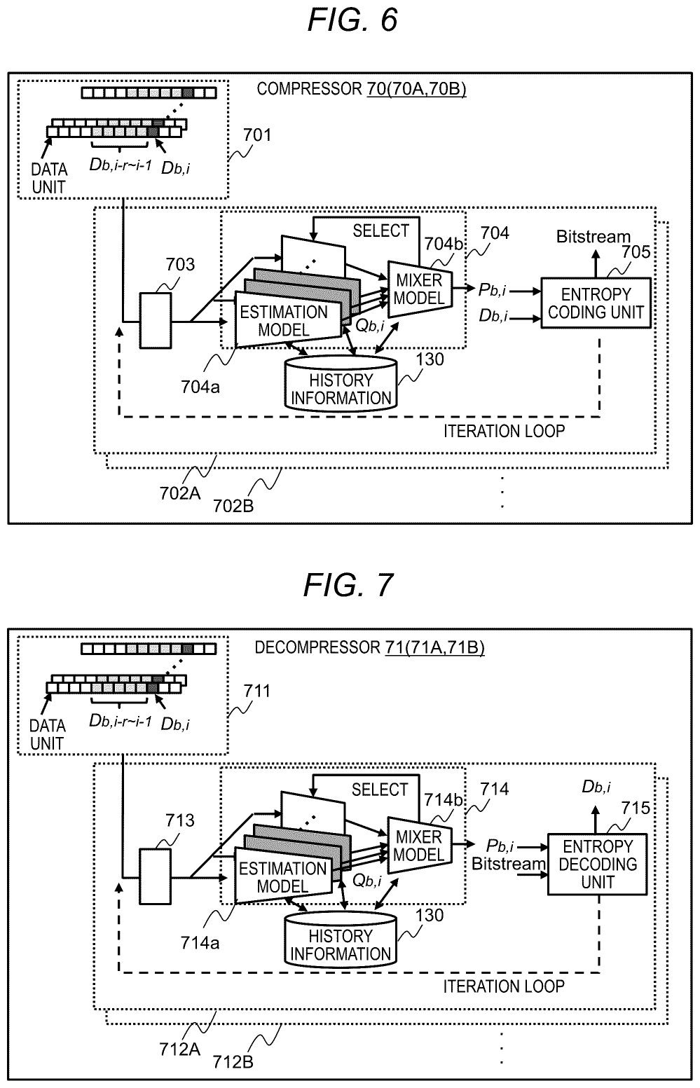

FIG. 6 is a diagram for describing a compressor according to the first embodiment.

The compressor 70 includes a data division unit 701 and a plurality of compression processing units 702 (702A, 702B, and the like). Each compression processing unit 702 is configured with each core 62 (62A, 62B) of the parallel processing device 61 (61A, 61B) executing programs in the memory 63 (63A, 63B). Here, a learning unit and a model selection unit are configured with the compression processing unit 702 executing programs.

The data division unit 701 divides the compression target data into a plurality of pieces of partial data (for example, 1 KB). In the present embodiment, the data division unit 701 divides the data into partial data by the number of batches B to be executed in parallel. In the compressor 70, the same number of compression processing units 702 as the number of batches B are used for processing, and each compression processing unit 702 performs the compression processing on each piece of partial data. The compression target data can further increase the number of partial data to be divided by collectively processing a plurality of pieces of block data at the same time, for example, can increase the parallel degree of processing on the parallel processing device 61B, and increase the speed.

The compression processing unit 702 includes a pre-coding unit 703 as an example of a conversion unit, a probability calculation unit 704, and an entropy coding unit 705.

When the partial compression target data is binary data, the pre-coding unit 703 performs one-hot encoding for each data unit of a predetermined size (u bits) included in the partial data. According to the pre-coding unit 703, one data unit is converted into 2^{u} bits. Data coded by the pre-coding unit 703 becomes the number of channels (C) input to the probability calculation unit 704. Note that, when one-hot encoding is performed, for the value of one predetermined bit of coded data for one data unit, the value can be specified according to the values of the remaining bits, and thus the predetermined one bit of the coded data may be deleted to make the number of channels C=2^{u}−1. By reducing the number of channels as such, the data volume input to the probability calculation unit 704 can be reduced. Note that the data used as input to the plurality of probability calculation units 704 is an array of number of batches of partial data (B)*number of channels (C)*length (N). Note that auxiliary information may be further added to the channel dimension of the data used for input. For example, by bit-encoding and adding the logical address 110a in units of bits corresponding to the partial data (adding the number of bits corresponding to the maximum value of the logical address in addition to the 2u bits), the accuracy of the estimation model for the target data can be improved, and the compression ratio can be improved. When the partial compression target data is numerical data or is binary data but can be expressed as a numerical value (such as sensor data or image data), the pre-coding unit 703 may input the numerical value to the probability calculation unit 704 as numerical data. Generally, it is assumed that numerical data files and text or binary data files coexist in the data on storage, and thus, for more efficient compression, a plurality of models such as an estimation model 704a for numerical data and the estimation model 704a for text or binary data files may be prepared.

The pre-coding unit 703 computes a hash value of the partial compression target data, and compares the hash values to detect overlap with previously processed partial data. Regarding the overlapping data, the pre-coding unit 703 saves only the reference information to the previously processed partial data in the address mapping table 110 or the block data storage information 120, and accordingly, it is not necessary to recompress and save the same data, and compression ratio can be increased. Here, the subsequent compression processing may be omitted to speed up the processing.

The probability calculation unit 704 includes a plurality of types of estimation models 704a and a mixer model 704b.

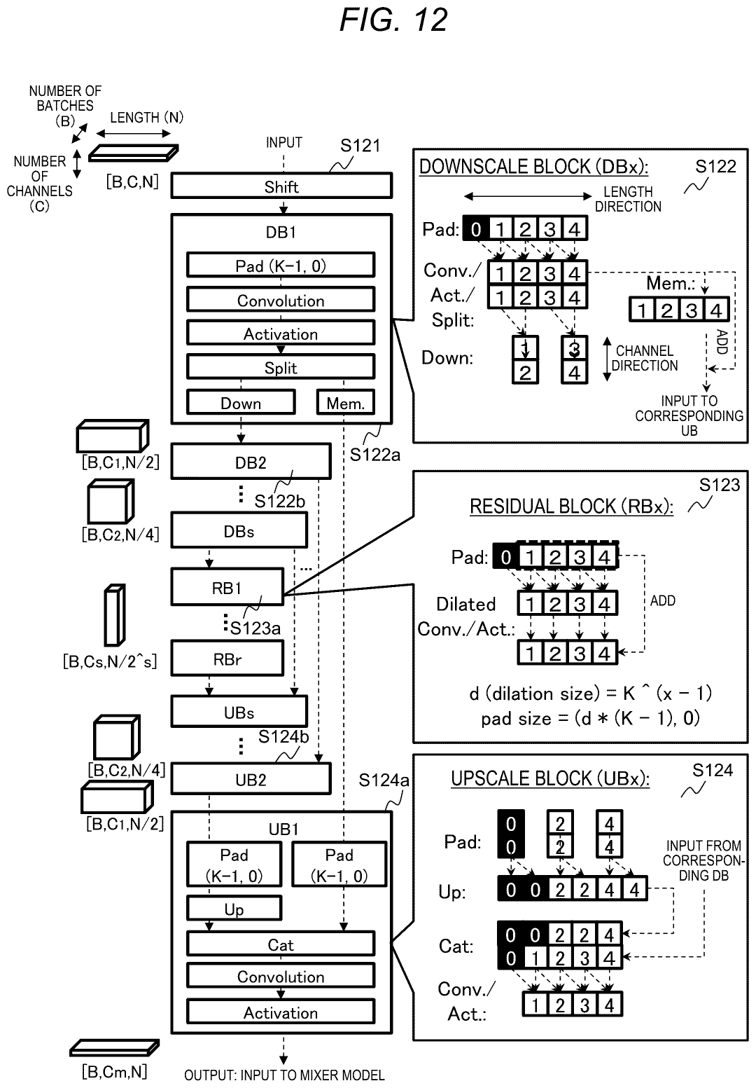

The estimation model 704a outputs estimation information Qb, i in units of estimation target data by inputting data (estimation data) used to estimate the data unit of which the appearance probability is to be estimated (estimation target data unit) and probability distribution information of the history information 130. Here, the estimation data may use, for example, a data unit of data units Db, i−r to Db, i−1, where the estimation target data unit is Db, i (i is the location of the estimation data unit in the partial data), that is, may use r data units immediately before the estimation target data unit. Note that, when r data units do not exist immediately before Db, i, processing is performed on the assumption that the missing data units have a predetermined value. The estimation model 704a may be a model configured with a plurality of learnable weights such as a neural network, or may be a model configured to execute a specific predefined processing. The estimation model 704a may output the appearance probability as the estimation information Qb, i, or may output a feature map of a location corresponding to the estimation target data unit. When outputting the appearance probability as the estimation information Qb, i, a discrete probability (such as a categorical distribution) may be output as the appearance probability for each symbol, parameters (average, variance, and the like) of a continuous probability density function such as Gaussian distribution may be output, or a result of calculating a discrete probability corresponding to the appearance probability of each symbol from a cumulative distribution function of a continuous probability density function may be output. An example of the configuration of the estimation model 704a will be described later with reference to FIGS. 12 to 14.

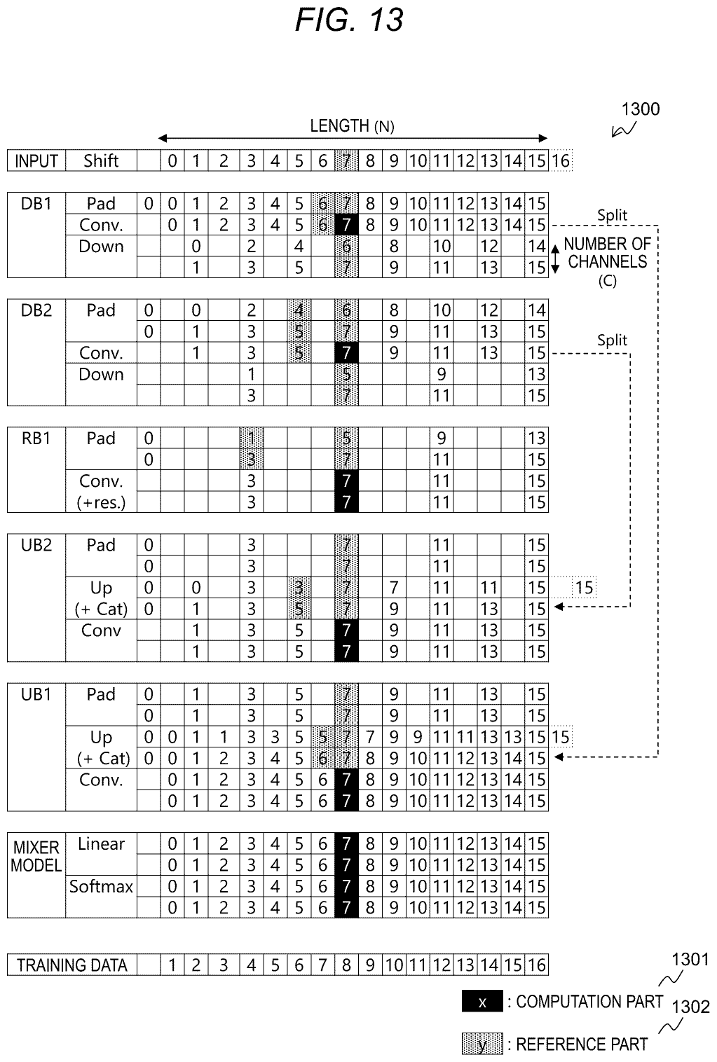

The mixer model 704b outputs (calculates) an appearance probability Pb, i of the estimation target data unit by inputting the estimation information output from the plurality of types of estimation models 704a and the probability distribution information of the history information 130. The appearance probability Pb, i is the distribution of the appearance probability for each symbol in the data unit, may output a discrete probability (such as a categorical distribution), and may output the parameters (average, variance, and the like) of a continuous probability density function such as Gaussian distribution as the appearance probability and use the result obtained by calculating the discrete probability corresponding to the appearance probability for each symbol from the cumulative distribution function during entropy coding. That is, when one-hot encoding is performed, the number of elements is the same as the number of channels input to probability calculation unit 704 (C=2^{u} or 2^{u}−1). The mixer model 704b is a model such as a neural network, and may be, for example, a gated linear network that integrates values input from each estimation model 704a using learned weights, or may be configured with a perceptron. Attention processing based on the output result of the estimation model (multiplying the data processed in the mixer model 704b by a value corresponding to a degree of importance calculated from the output result of the estimation model) may be included. In the present embodiment, the probability calculation unit 704 selects an estimation model to be used for processing from among the plurality of types of estimation models 704a, based on the weight for each estimation model 704a in the mixer model 704b. Note that the history information 130 may be provided for each compression processing unit 702 or may be shared by a plurality of compression processing units 702. In particular, when each data unit has locality, by sharing the history information 130, it is possible to increase the number of statistical samples of the probability distribution, and thus estimation accuracy can be improved, the compression ratio can be increased, and the usage of the memory 63B, for example, can be saved. An example of the configuration of the mixer model 704b will be described later with reference to FIG. 13.

The entropy coding unit 705 takes the appearance probability Pb, i output from the probability calculation unit 704 and the data unit Db, i as inputs, and outputs a bit string (coded bit string) obtained by entropy-coding the data unit Db, i.

Each compression processing unit 702 entropy-codes the entire partial data by sequentially changing the compression target and repeating the processing, for example, from the data unit at the head, using the data unit in the partial data as a unit. The processing by the each compression processing unit 702 is executed in parallel, for example, in the dimension of the number of batches (B), and thus the efficiency of the compression processing can be improved. Since the results of a plurality of estimation models are integrated to calculate the appearance probability, a highly accurate appearance probability can be calculated and compression efficiency can be improved.

The compressor 70 collects the bit streams (second block corresponding bit string group) for each piece of the partial data obtained by the plurality of compression processing units 702 in a state where the data range corresponding to each piece of partial data is identifiable, and uses the collected bit streams as compressed data of the compression target data. Here, the storage processing unit is configured with the compressor 70.

Next, the configuration and processing of the decompressor 71 (71A, 71B) will be described.

FIG. 7 is a diagram for describing a decompressor according to the first embodiment.

The decompressor 71 decompresses the compressed data compressed by the compressor 70. The decompressor 71 includes a data synthesis unit 711 and a plurality of decompression processing units 712 (712A, 712B, and the like). Each decompression processing unit 712 is configured with each core 62 (62A, 62B) of the parallel processing device 61 (61A, 61B) executing programs in the memory 63 (63A, 63B). Here, the first block corresponding guarantee code creation unit is configured with the decompressor 71 executing programs.

The data synthesis unit 711 synthesizes partial data configured with data units decompressed by each decompression processing unit 712 to generate data before compression. In the present embodiment, the data synthesis unit 711 synthesizes partial data of the number of batches B during compression of the compressed data. In the decompressor 71, the same number of decompression processing units 712 as the number of batches B are used for processing, and each decompression processing unit 712 respectively performs decompression processing on partial data.

The decompression processing unit 712 includes a pre-coding unit 713, a probability calculation unit 714 as an example of a second probability calculation unit, and an entropy decoding unit 715.

The pre-coding unit 713 performs the same processing as the pre-coding unit 703. The probability calculation unit 714 performs the same processing as the probability calculation unit 704.

When the appearance probability Pb, i output from the probability calculation unit 714 and the bit string corresponding to the data unit Db, i to be decoded in the compressed data are input, the entropy decoding unit 715 decodes the bit string and outputs the data unit Db, i.

Each decompression processing unit 712 entropy-decodes the entire bit string of the entropy-coded partial data by sequentially changing the decompression target and repeating the processing, for example, from the data unit at the head, for each data unit in the partial data. The processing by each decompression processing unit 712 is executed in parallel, for example, in the dimension of the number of batches (B), and thus the efficiency of the decompression processing can be improved.

Next, the processing operation of the compression processing by the compressor 70 will be described.

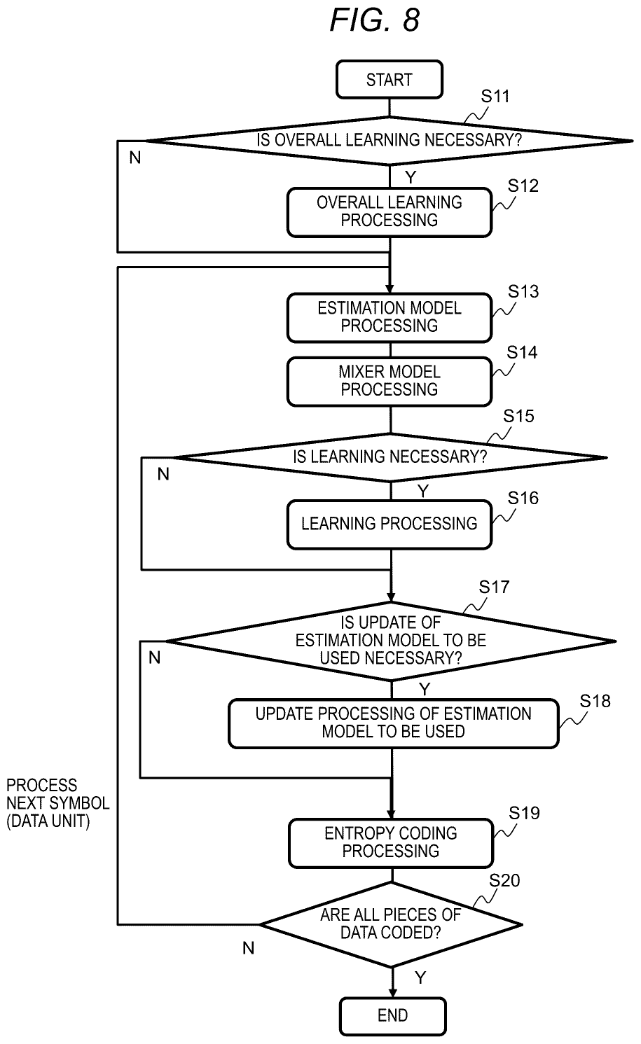

FIG. 8 is a flowchart of the compression processing by the compressor according to the first embodiment. Note that the compression processing shown in FIG. 8 is processing executed by each compression processing unit 702 of the compressor 70, and can be implemented by, for example, a thread operating in the core 62B of the parallel processing device 61B.

The compression processing unit 702 of the compressor 70 determines whether overall learning is necessary (S11). For example, whether overall learning is necessary is determined based on the effect that the compression target data can be highly compressed by fully learning a new model, and the total compression effect including an overhead of storage capacity for saving newly learned models.

As a result, when it is determined that the overall learning of the estimation model 704a or the mixer model 704b is necessary (S11: Y), the compression processing unit 702 performs the overall learning processing (S12), and the corresponding model is used in the estimation model processing and the mixer model processing used in subsequent processing. The overall learning processing is processing of using data that are close to each other in the logical address space for learning and saving the learned model, based on the hypothesis that data that are close to each other in the logical address space have similar characteristics of the appearance probabilities of the data symbols. The learning data may be partial data of the compression target data designated at the time of activating the processing flow, or other data may be used. For example, the learning data may be randomly sampled from data stored in the storage based on a predetermined rule. The learned model is saved as the model information 120d of the block data storage information 120 in association with the compressed data. Otherwise, by storing reference information of other corresponding models (models corresponding to other block data that was already learned) (that is, reusing the already learned model), the processing time for overall learning and the data volume in block data storage information may be reduced. In learning, technologies such as transfer learning and meta-learning may be used to speed up the learning.

Meanwhile, when it is determined that the overall learning is not necessary (S11: N), the compression processing unit 702 proceeds the processing to step S13. Here, in the estimation model processing and the mixer model processing used in subsequent processing, the initial values of the parameters are initialized using values that can be generated by mathematical formulas (for example, pseudorandom numbers based on Gaussian distribution).

Next, the compression processing unit 702 performs one-hot encoding as necessary on the data used for calculating the appearance probability of a data unit to be compressed (compression target data unit: at first, the data unit at the head, and thereafter, the next data unit) of the partial data that the compression processing unit 702 itself is in charge of, and performs estimation model processing of inputting data into a plurality of estimation models 704a and calculating a plurality of appearance probabilities using the plurality of estimation models (S13).

Next, the compression processing unit 702 performs the mixer model processing of inputting the plurality of pieces of estimation information calculated by the estimation model processing into the mixer model 704b, and calculating the appearance probability of the compression target data unit (S14).

Next, the compression processing unit 702 determines whether learning of the estimation model 704a and the mixer model 704b is necessary (S15). For example, it may be determined that learning is necessary when the determination in step S15 is performed a predetermined number of times.

As a result, when it is determined that learning of the mixer model 704b is necessary (S15: Y), the compression processing unit 702 performs learning processing of the estimation model 704a and the mixer model 704b (S16), and then proceeds the processing to step S15. The data used for learning is data that is already decoded at this point when decompression is assumed, and data prepared in advance and/or historical data may be used. According to the learning processing, the weights stored by the plurality of estimation models 704a and the mixer model 704b are corrected.

Meanwhile, as a result, when it is determined that learning of the mixer model 704b is not necessary (S15: N), the compression processing unit 702 proceeds the processing to step S17.

In step S17, the compression processing unit 702 determines whether it is necessary to update the estimation model actually used among the plurality of estimation models. For example, as the weights for each estimation model are changed by learning of the mixer model 704b, when the weight for the estimation model becomes equal to or less than a predetermined threshold value, it may be determined that the estimation model to be used needs to be updated.

As a result, when it is determined that the estimation model to be used needs to be updated (S17: Y), the compression processing unit 702 executes usage estimation model update processing (S18), where estimation models of which corresponding weights are equal to or less than a predetermined value among the estimation models are set to be not used, and proceeds the processing to step S19.

Meanwhile, when it is determined that it is not necessary to update the estimation model to be used (S17: N), the compression processing unit 702 proceeds the processing to step S19.

In step S19, the compression processing unit 702 converts the compression target data unit into an entropy-coded bit string by performing entropy coding processing using the appearance probability output in step S14 and the compression target data unit.

Next, the compression processing unit 702 determines whether all the data units of the partial data were coded (S20), and when all the data units were not coded (S20: N), the processing is proceeded to step S13 for the processing of the next data unit.

Meanwhile, when all data units were coded (S20: Y), the processing ends. Note that, next, the compressor 70 collects the coded bit strings of the partial data converted by each compression processing unit 702 and stores the bit strings as compressed data in a predetermined storage location.

In the above description, an example was described in which the estimation model processing, the mixer model processing, the learning processing, and the entropy coding processing are iterated in order for each data unit, but the execution unit and timing of the processing can be changed. For example, in the estimation model processing and the mixer model processing, since all original data exists during compression, for example, as shown in FIG. 12, the processing can be executed collectively in parallel in the length (N) direction. When a method such as asymmetric numeral systems (ANS) is used in the entropy coding processing (S19), since the decoding processing needs to be executed in the reverse order of the coding, during the compression, the appearance probability of the results estimated in the estimation model processing and the mixer model processing is saved in the length (N) direction, and when a series of computations in the length (N) direction is completed, the entropy coding processing is executed collectively in the reverse order for the saved appearance probabilities. In the learning processing, in addition to the method of executing in the length (N) direction (learning using data before the current point of iteration in the length (N) direction), for example, a plurality of data blocks, which are compression targets, may be sampled and used as learning target data. Here, to ensure that the learning target data can be uniquely specified and not included in the data before decompression, sampling may be performed using deterministic pseudorandom numbers and the like to determine the learning data and schedule for compression. The processing order of data units in the length (N) direction does not have to be the original order, but may be changed using a reversible algorithm. A method such as a diffusion model that restores original data from a state of noise may be used, and the unit of iteration may correspond to one step of the diffusion model. When changing the execution unit and timing respectively as described above, in any case, by performing decompression using the same execution unit and timing, and by setting the appearance probability of the estimated results to be the same, the result can be decoded.

Next, the processing operation of the decompression processing by the decompressor 71 will be described.

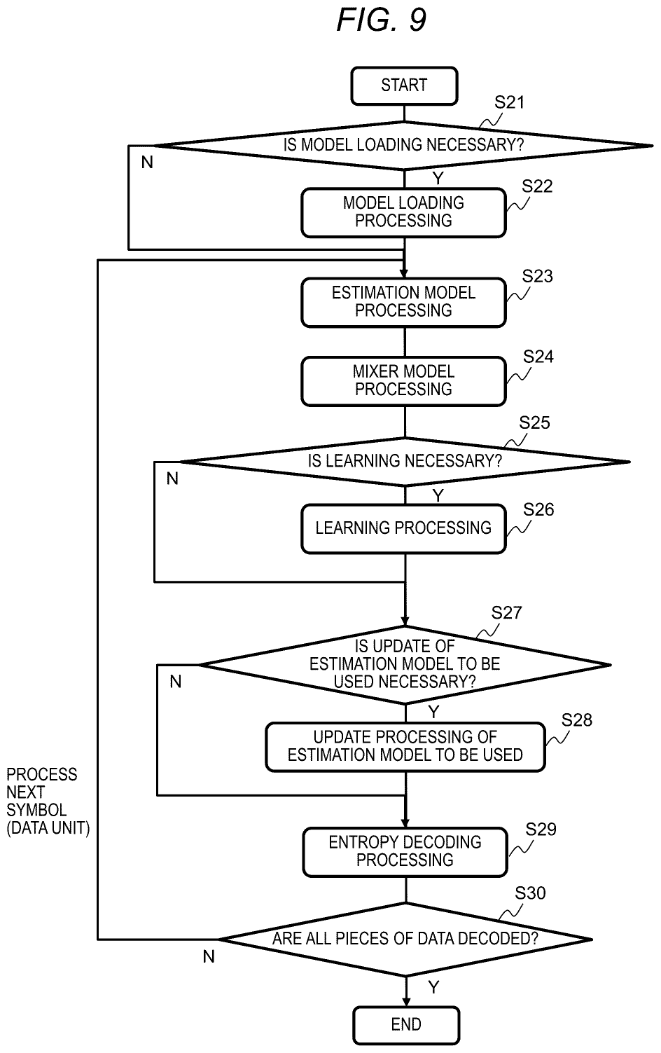

FIG. 9 is a flowchart of decompression processing by the decompressor according to the first embodiment. Note that the decompression processing shown in FIG. 9 is processing executed by each decompression processing unit 712 of the decompressor 71, and can be realized by, for example, a thread operating in the core 62B of the parallel processing device 61B.

The decompression processing unit 712 of the decompressor 71 determines whether model loading is necessary (S21). For example, regarding whether model loading is necessary, when the parameters and references of the model itself e saved in association with the compressed data as the model information 120d of the block data storage information 120, it is determined that model loading is necessary, and when the parameters and references are not saved, it is determined that model loading is not necessary.

As a result, when it is determined that model loading of the estimation model 704a or the mixer model 704b is necessary (S21: Y), a model is placed in the memory 63B of the parallel processing device 61B as the model information 120d based on the parameters and references of the model itself corresponding to the compressed data. The memory 63B of the parallel processing device 61B may be used like a cache. Here, when the model was already loaded into the memory 63B used as a cache (models that are used frequently may be placed in the memory 63B like a cache) in the determination of S21, model loading can be omitted, and thus it can be determined that model loading is not necessary, and the time required for model loading can be efficiently reduced.

Meanwhile, when it is determined that the model loading is not necessary (S21: N), the decompression processing unit 712 proceeds the processing to step S23. Here, in the estimation model processing and the mixer model processing used in the subsequent processing, by the same method as the method used when the entire model learning of the compression processing unit 702 described above is not performed (S11: N) is used, the initial value of the parameter is initialized using a value that can be generated by a mathematical formula (for example, a pseudorandom number based on a Gaussian distribution).

Next, the decompression processing unit 712 performs one-hot encoding on the data used for calculating the appearance probability of a data unit to be compressed (compression target data unit: at first, the data unit at the head, and thereafter, the next data unit) of the partial data that the decompression processing unit 712 itself is in charge of, and performs estimation model processing of inputting data into a plurality of estimation models 714a and calculating a plurality of pieces of estimation information using the plurality of estimation models (S23).

Next, the decompression processing unit 712 performs the mixer model processing of inputting the plurality of pieces of estimation information calculated by the estimation model processing into the mixer model 714b, and calculating the appearance probability of the compression target data unit (S24).

Next, the decompression processing unit 712 determines whether learning of the estimation model 714a and the mixer model 714b is necessary (S25). For example, it may be determined that learning is necessary when the determination in step S25 is performed a predetermined number of times.

As a result, when it is determined that learning of the estimation model 714a and the mixer model 714b is necessary (S25: Y), the decompression processing unit 712 performs learning processing of the estimation model 714a and the mixer model 714b (S26), and then proceeds the processing to step S27. The data used for learning processing is data that is already decoded at this point, and data prepared in advance and/or historical data may be used. According to the learning processing, the weights stored by the estimation model 714a and the mixer model 714b are corrected.

Meanwhile, as a result, when it is determined that it is not necessary to perform learning of the estimation model 714a and the mixer model 714b (S25: N), the decompression processing unit 712 proceeds the processing to step S27.

In step S27, the decompression processing unit 712 determines whether it is necessary to update the estimation model actually used among the plurality of estimation models. For example, as the weights for each estimation model are changed by learning of the mixer model 714b, when the weight for the estimation model becomes equal to or less than a predetermined threshold value, it may be determined that the estimation model to be used needs to be updated.

As a result, when it is determined that it is necessary to update the estimation model to be used (S27: Y), the decompression processing unit 712 executes usage estimation model update processing (S28), where estimation models of which corresponding weights are equal to or less than a predetermined value among the estimation models are set to be not used, and proceeds the processing to step S29.

Meanwhile, when it is determined that it is not necessary to update the estimation model to be used (S27: N), the decompression processing unit 712 proceeds the processing to step S29.

In step S29, the decompression processing unit 712 performs entropy decoding processing using the appearance probability output in step S24 and the entropy-coded bit string corresponding to the decompression target data unit to decode the entropy-coded bit string into data units before coding.

Next, the decompression processing unit 712 determines whether all the data units of the partial data were encoded (S30), and when all the data units were not encoded (S30: N), the processing is proceeded to step S23 for the processing of the next data unit.

Meanwhile, when all data units were decoded (S30: Y), the decompression processing unit 712 ends the processing. Note that, next, the decompressor 71 collects the partial data converted by each decompression processing unit 712 and stores the collected partial data in a predetermined storage location as decompressed data.

As described above, each processing necessary for decompression of a plurality of data units by the decompression processing unit 712 is consistently executed in a loop on a thread running on the core 62B of the parallel processing device 61B, and accordingly, it is possible to reduce the processing time required for activating communication or threads necessary for command transmission or the like between the processor 53B and the core 62B of the parallel processing device 61B, and high-speed processing becomes possible. Note that the calculation of the appearance probability of the data unit in steps S23 to S30, the learning processing, the update processing of the usage model, and other determination processing are the same as the calculation of the appearance probability of the data unit in the compression processing, and thus for the same data unit, the same appearance probability can be calculated, and can be appropriately decoded.

Regarding the compression processing and the decompression processing described in FIGS. 8 and 9, respectively, when the learning and usage estimation model update processing in S16, S18, S24, and S26 are not operated, or when the state of each piece of partial data is managed and operated independently, based on the compressed size 120c of the block data storage information 120, it is possible to perform the recompression or decompression processing for data update for each piece of partial data of data to be compressed and decompressed. As a result, even when a large block (for example, several MB to several GB) was already highly compressed, it is possible to partially update and decompress data in units of partial data without decompressing all the data in the block, and thus the amount of required computing resources can be reduced.

Next, the processing operation of the backup processing in the computer 101B will be described.

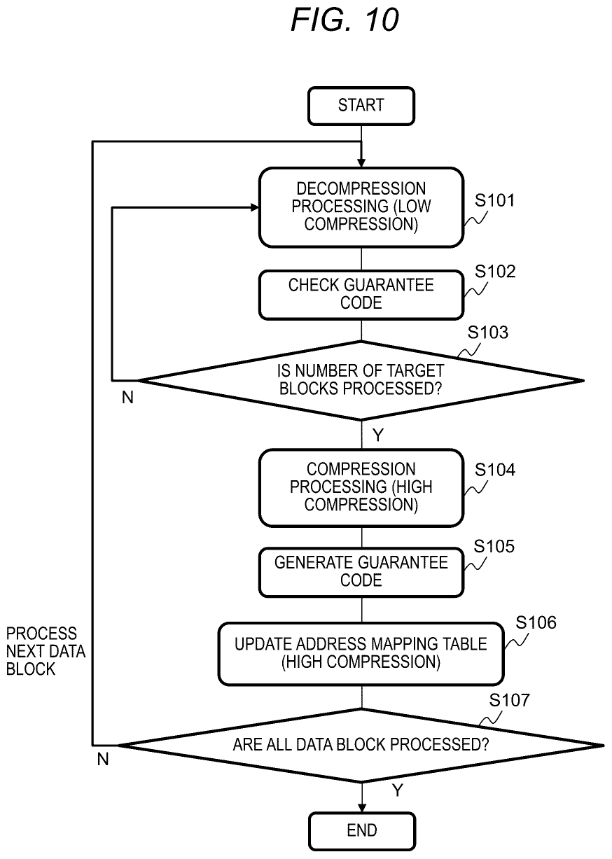

FIG. 10 is a flowchart of the backup processing according to the first embodiment.

The backup processing is executed when the processor 53B of the computer 101B receives, from the computer 101A, a compression command to which the backup target data block groups (first compressed data) compressed by the compressor 72A and a guarantee code group are added. The processor 53B causes the decompressor 73B to execute decompression processing on one backup target data block (first block unit) (S101). Note that the compression performed by the compressor 72A is lower compression than the compression performed by the compressor 70B.

Next, the processor 53B checks the decompressed data (decompressed data) using the added guarantee code, and performs processing such as error detection or correction (S102).

Next, the processor r 53B determines whether the decompression processing was performed on the number of blocks (number of target blocks) corresponding to a predetermined size (second size) to be compressed in the next compression processing (S103).

As a result, when the decompression processing was not executed for the blocks corresponding to the number of target blocks (S103: N), the processor 53B proceeds the processing to step S101 and executes the processing for the next data block.

Meanwhile, when the decompression processing is being executed on the blocks corresponding to the number of target blocks (S103: Y), the processor 53B executes the compression processing by the compressor 70B for the data of the blocks (second block unit) corresponding to the number of target blocks (S104). The compression processing by the compressor 70B is the compression processing shown in FIG. 8, and the compression by the compressor 70B is higher compression than the compression by the compressor 72. Note that the throughput of the compression processing can be improved by dividing the data of the number of target blocks into a plurality of data units and for example, by collectively compressing the data in parallel by the core 62B of the parallel processing device 61B. Since the size of the data to be compressed (second size) is larger than the size of the data compressed by the compressor 72 (first size), compression efficiency is good.

Next, the processor 53B generates a guarantee code for the data of blocks (second block units) corresponding to the number of target blocks (S105), stores the compressed data 120a, the guarantee code 120b, the compressed size 120c, and the model information 120d as the block data storage information 120 in the persistent storage device 54B, and updates the address mapping table 110 according to the stored content (S106). Here, since the guarantee code is generated for the data of the second size, the storage area required to store the guarantee code can be reduced. When collecting a plurality of data blocks in the first block unit to form a second block unit, zero-filled data may be prepared for the area to which no physical address was originally assigned in the first block, and data necessary for restoration equivalent to the address mapping table 110 in first block units may be saved together with the block data storage information. When it is necessary to save the address mapping table 110 in the persistent storage device 54, by compressing the address mapping table 110 itself in a similar manner as a target of the compression processing (S104), the capacity used in the persistent storage device 54 may be saved and efficiency may be improved. The guarantee code 120b and the model information 120d themselves may also be compressed in a similar manner as targets of compression processing (S104). The compressed size 120c is obtained as a result of the compression processing (S104), and thus the compression efficiency may be improved by performing the same process as the compression processing (S104) again or by using another general compression method.

Next, the processor 53B determines whether all compression target data blocks were processed (S107). As a result, when all the compression target data blocks were not processed (S107: N), the processor 53B proceeds the processing to step S101 and executes the processing on the remaining data blocks.

Meanwhile, when all the compression target data blocks were processed (S107: Y), the processor 53B notifies the request source computer 101A that the backup was completed, and ends the processing.

Next, the processing operation of the restoration processing in the computer 101B will be described.

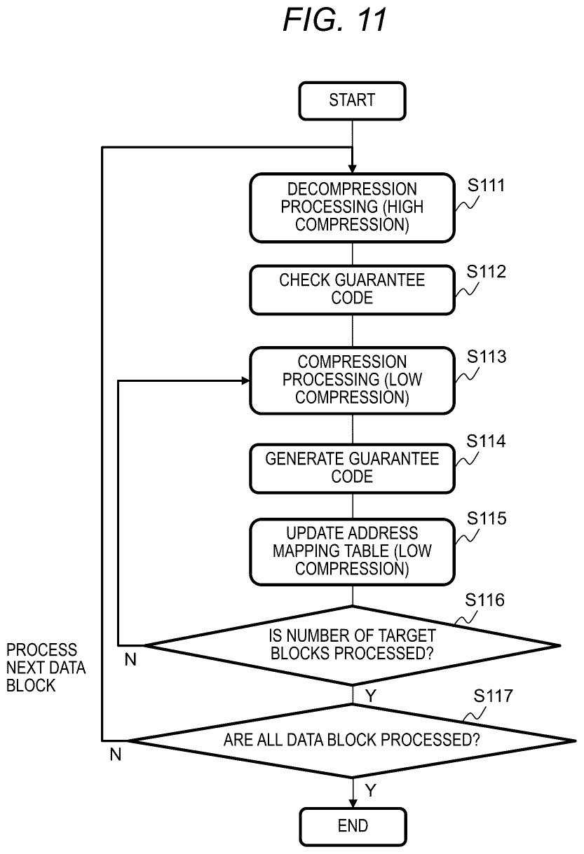

FIG. 11 is a flowchart of the restoration processing according to the first embodiment.

The restoration processing is executed when the processor 53B of the computer 101B receives, from the computer 101A, a restore command to which information indicating restoration target data block groups is added. Note that the data blocks of the data block group are blocks obtained by compressing data of the first size.

First, the processor 53B causes the decompressor 71B to execute decompression processing on one data block of the second size that includes restoration target data block groups corresponding to the restore command (S111). Note that, similar to the compression, the throughput of the decompression processing can be improved by dividing the data of the number of target blocks into a plurality of data units and for example, by collectively decompressing the data in parallel by the core 62B of the parallel processing device 61B.

Next, the processor 53B checks the decompressed data using the added guarantee code, and performs processing such as error detection or correction (S112).

Next, the processor 53B causes the compressor 72B to execute compression processing on the block data of the first size in the decompressed data (S113).

Next, the processor 53B generates a guarantee code for the block data of the first size (S114), stores the block data and the guarantee code in the persistent storage device 54B, and updates the address mapping table 110 for the block of the first size according to the stored contents (S115).

Next, the processor 53B determines whether the compression processing was performed on the blocks corresponding to the number of blocks of the first size (number of target blocks) included in the block data of the second size (S116).

As a result, when the compression processing was not executed for the blocks corresponding to the number of target blocks (S116: N), the processor 53B proceeds the processing to step S113 and executes the processing for the remaining block data of the first size.

Meanwhile, when the compression processing is being executed on the blocks corresponding to the number of target blocks (S116: Y), it is determined whether the processor 53B already executed the processing on all the data blocks that include the restoration target data block group (S117).

As a result, when all data blocks including the restoration target data block group were not processed (S117: N), the processor 53B proceeds the processing to step S111 and executes the processing for the remaining data blocks.

Meanwhile, when all data blocks including the restoration target data block group were processed (S117: Y), the processor 53B transmits a compressed data group, which is a collection of compressed data for each piece of block data of the first size (each first block unit), and a guarantee code group, which is a collection of corresponding guarantee codes, to the request source computer 101A, and ends the processing.

Next, the processing operation of the estimation model processing in the computer 101B will be described.

FIG. 12 is a diagram for describing the estimation model processing according to the first embodiment.

The processing is an example of the estimation model 704a and the estimation model 714a (executed by the compression processing unit 702 and the decompression processing unit 712) (simply referred to as an estimation model). The estimation model processing is an example of a case of configuring processing of the estimation model using a neural network, and is performed by inputting data (estimation data) used to estimate the data unit of which the appearance probability is the estimation target (estimation target data unit) to output a feature map (data to be input to the mixer model) of the location corresponding to the estimation target data unit. The processing can be executed in parallel as threads for each dimension of the number of batches (B) operated on the core 62B of the parallel processing device 61B, for example.

The data input here is an array of number of batches (B)*number of channels (C)*length of partial data (N). Note that during estimation model learning and compression, all pieces of compression target data are stored, and thus the plurality of pieces of estimation target data (N direction) can be processed collectively in parallel after matching the causal relationships of the data. The description of FIG. 12 is for the case where the processing are collectively performed. Meanwhile, during decompression (decoding), data that decoding is not completed is not stored, and thus the operation then will be described with reference to FIG. 13.

The estimation model processing is mainly configured with functional components which are referred to as shift processing of input data (S121), downscale block (DB) (S122), residual block (RB) (S123), and upscale block (UB) (S124) (hereinafter, the components will be collectively referred to as scale causal blocks (SCB)).

The input data shift processing (S121) is processing of padding the input data by one piece at the head in the length (N) direction and deleting one piece from the rear end. By the processing, the input data is moved by one piece to the past in the length (N) direction, and accordingly, the subsequent processing is processing of estimating the next input data from the past data.

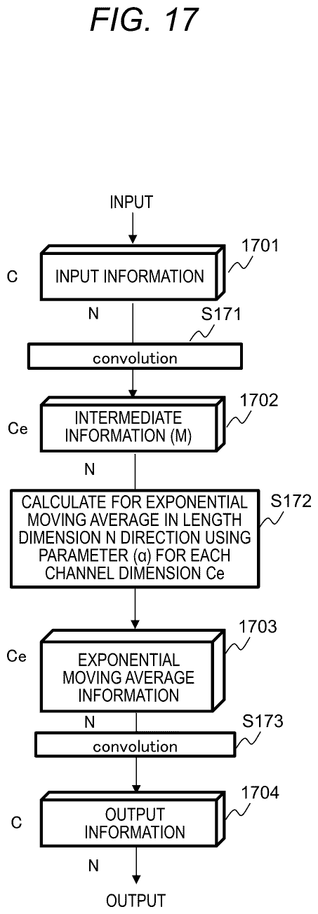

The downscale block (S122) is processing of processing input data with a convolutional neural network, dividing the data in the channel dimension direction (C direction), and then reducing the length (N) direction. Specifically, first, the data being processed is padded at the head in the length (N) direction with a predetermined size (for example, K−1 pieces) (indicated by black “0” in FIG. 12), and processes a convolutional neural network (Convolution in the drawing). In the example, since the length (N) direction is one-dimensional, a one-dimensional convolutional neural network is applied. Note that a kernel size of the convolutional neural network is K, and a stride width is 1. The kernel size may be set to K=2, for example, from the viewpoint of the range of the receptive field relative to the number of weights in the neural network. Next, an activation function (Activation in the drawing) is applied to the data being processed (output result of the convolutional neural network). As the activation function, a function such as scaled exponential linear unit (SELU) or rectified linear unit (ReLU) may be used. Thereafter, the data being processed is divided (Split in the drawing) in the channel dimension direction (C direction). A part of the divided data is used as a direct input to the subsequent corresponding upscale block (S124) without going through the processing of the subsequent downscale block (S122). Accordingly, it is possible to prevent the loss of fine-grained information due to the processing of reducing the length (N) direction by the downscale block (S122), and further improve the accuracy of the estimation model processing. Processing of a memory model (Mem. in the drawing) may be applied to a part of the divided data. The memory model is processing exemplified by FIGS. 16 and 17, which will be described later, and is processing for improving probability estimation accuracy by storing history information in the length direction. The memory model may be configured in the form of a residual block, as shown in the diagram of the downscale block (S122). Thereafter, processing (Down in the drawing) is executed to reduce the length (N) direction of the data being processed. The reduction processing may be performed, for example, by replacing two consecutive pieces of data in the length (N) direction with the channel (C) direction, as shown in FIG. 12. As other methods, processing may be performed using a convolutional neural network with a wide stride width, or a method such as pooling may be used. In S122 of FIG. 12, an overview of the above processing is shown, and the numbers in the drawing represent the numbers corresponding to the order in the length (N) direction of the input data unit, and in the processing after Convolution, the numbers in the drawing represent the causal relationship between the numbers of the order of input data and the processing results corresponding to the numbers (the maximum value of the number corresponding to the information used in the processing). In the above processing, the causal relationship in the length (N) direction of the input data is saved. In other words, since information after a certain target data unit is not used for processing, the processing is established as estimation processing.

The residual block (S123) is processing in which the data output from the preceding functional component is processed by a dilated convolutional neural network, and the processed data and the unprocessed data are added. Specifically, the data being processed is first padded with a predetermined size (for example, d*(K−1) pieces) at the head in the length (N) direction, and then processed by the dilated convolutional neural network. In the example, since the length (N) direction is one-dimensional, a one-dimensional convolutional neural network is applied. Note that the kernel size of the dilated convolutional neural network is K (for example, K=2), the stride width is 1, and a dilated size d is K^{x-1}. Here, x is the level of the residual block, and when r residual blocks are configured as shown in FIG. 12, the order of processing is designated by a natural number from 1 to r. By increasing the dilated size for each level of the hierarchy as described above, the receptive field in the length (N) direction can be efficiently widened. Next, an activation function is applied, similarly to the downscale block (S122). Thereafter, the processed data and the unprocessed data are added together to provide the output result of the residual block (S123). In addition to the addition processing, attention processing (such as self-attention) may be introduced. In the above processing, as shown in S123 of FIG. 12, it can be seen that the causal relationship in the length (N) direction of the input data is saved, similarly to the downscale block (S122), and the processing is established as estimation processing.

The upscale block (S124) expands the data output from the preceding functional component in the length (N) direction, combines the data divided by the preceding corresponding downscale block (S124) and outputs the processed data by a convolutional neural network. Specifically, first, the data being processed is padded with a predetermined size (for example, K−1 pieces) at the head of the data in the length (N) direction, and then expanded in the length (N) direction (Up in the drawing). For example, as shown in FIG. 12, in the reverse processing of Down of the downscale block (S122), the processing may be performed by dividing the data into two pieces in the channel (C) direction, and replacing the data with two pieces of data that are continuous in the length (N) direction. As another method, processing may be performed using a transposed convolutional neural network with a widened stride width. Regarding the data being processed divided into corresponding downscale blocks (DBx) that have the same length in the length (N) direction, the data is padded with a predetermined size (for example, K−1 pieces) at the head in the length (N) direction to create data combined in the channel (C) direction with the data being processed, which was expanded in the length (N) direction. The data is processed using a convolutional neural network. In the example, since the length (N) direction is one-dimensional, a one-dimensional convolutional neural network is applied. Note that the kernel size of the convolutional neural network is K (for example, K=2), and the stride width is 1. Thereafter, the activation function is applied to the data being processed (the output result of the convolutional neural network), similarly to the downscale block (S122), and the resulting data is obtained. In the above processing, as shown in S124 of FIG. 12, it can be seen that the causal relationship in the length (N) direction of the input data is saved, similar to the downscale block (S122), and the processing is established as estimation processing.

As a method of configuring the functional components described above, for example, as shown in FIG. 12, first, a plurality (s pieces) of downscale blocks (S122) (DB1 to DBs) may be processed, then a plurality (r pieces) of residual blocks (S123) (RB1 to RBr) may be processed, and then a plurality (s pieces) of upscale blocks (S124) (UB1 to UBs) may be processed. By processing as such, the number of elements in the input data of B*C*N can be reduced to B*C1*N/2, B*C2*N/4 in the length (N) direction, the number of internal channels C1 to Cs can be efficiently increased, and thus the processing of the estimation model can be made more efficient and faster. Note that C1 to Cs may be increased along with the reduction in the length (N) direction when processing the downscale block (S122), and may be decreased along with the increase in the length (N) direction when processing the upscale block (S124). By combining the downscale block (S122), the residual block (S123), and the upscale block (S124), it is possible to have a wide receptive field with a length of K^{s+r}. In other words, it is possible to efficiently increase the data volume (estimation data) used to estimate the data unit for which the appearance probability is estimated (estimation target data unit), and thus estimation accuracy for a predetermined amount of processing can be improved. The residual block (S123) may be processed between a plurality of downscale blocks (S124) or between a plurality of upscale blocks (S124).

In a configuration using s downscale blocks (S122) and s upscale blocks (S124), by sharing the weights of each convolution layer of w blocks (RBs−w to RBs and UBS−w to UBs) (the convolution layers of RBs−w to RBs are the same as the parameters of the RBs−w convolution layer, and the convolution layers of UBs−w to UBs are the same as the parameters of the UBs−w convolution layer), the number of parameters in the estimation model may be reduced. Reducing the number of parameters of the estimation model can reduce the data volume of the model information 120d of the block data storage information 120, and thus, by appropriately setting w, compression efficiency can be improved.

The receptive field may be further expanded by increasing the kernel size (K) according to the layer depth (s) of the downscale block (S122) and the upscale block (S124).

The length (N) direction may be made multidimensional for multidimensional data such as image data. Then, similar processing may be performed using a convolutional neural network of the corresponding dimension.

Next, a data flow of the estimation model processing and the mixer model processing in the computer 101B will be described.

FIG. 13 is a diagram for describing a data flow of the estimation model processing and the mixer model processing according to the first embodiment.

Processing 1300 is an example of a method for implementing the estimation model 704a and the estimation model 714a (executed by the compression processing unit 702 and the decompression processing unit 712) (simply referred to as the estimation model), and the mixer model 704b and the mixer model 714b (executed by the compression processing unit 702 and the decompression processing unit 712) (simply referred to as the mixer model). The estimation model processing and the mixer model processing are the estimation model processing and the mixer model processing described in FIG. 12, and how data is processed within the processing will be described, including an overall overview. The first input data is an array of number of batches (B)*number of channels (C)*length of partial data (N), similarly to FIG. 12, but in the drawing, the dimension of the number of batches (B) is omitted, the horizontal axis represents the length (N) of partial data, the vertical axis represents the order of each processing, and the vertical axis in each processing represents the number of channels (C). The processing can be executed in parallel as threads for each dimension of the number of batches (B) operated on the core 62B of the parallel processing device 61B, for example.

The example shows processing of estimating eighth data from the front in the training data. Here, the eighth data unit is the data unit for which the appearance probability is estimated (estimation target data unit), and the data used for the estimation (estimation data) corresponds to a computation part 1301 and a reference part 1302 in the drawing. The reference part 1302 also includes results (stored as a cache, for example) computed in the past (in data units that were already estimated).

In the example, the estimation model processing is configured by two downscale blocks (S122) (DB1, DB2), one residual block (S123) (RB1), and two upscale blocks (S124) (UB1, UB2), and the mixer model processing is configured by a linear neural network (similar to convolution with K=1) and a Softmax function. In the estimation model processing, a feature map of the location corresponding to the estimation target data unit (data input to the mixer model) is output, and in the mixer model processing, the estimation result of the appearance probability of the estimation target data unit is finally output.

The numbers in the drawing represent the numbers corresponding to the order in the length (N) direction of the input data unit, and in each processing, the numbers in the drawing represent the causal relationship between the numbers of the order of the input data and the processing result corresponding to the number (the maximum value of the number corresponding to the information used in the processing). As a result of the mixer model processing, the causal relationship in the length (N) direction of the input data is saved. In other words, since information after a certain target data unit is not used for processing, the processing is established as estimation processing.

Regarding the estimation model processing, processing is proceeded in the same manner as the method which was already described in FIG. 12. However, in the example, to proceed the computation for the computation part 1301 in the drawing, it is shown that the data of the reference part 1302 is cached in a state where overlaps are removed when computing the past (seventh or earlier) appearance probabilities, and by using the cached data, the computation of the computation part 1301 can be proceeded efficiently. As such, even when it is difficult to perform computations collectively in the length (N) direction during decoding, high-speed processing can be achieved through efficient iteration processing that prevents overlap of computations.

Regarding the mixer model processing, the example describes the case where one estimation model is used, but a plurality of estimation models may be used similarly. Then, the input dimension of the neural network of the mixer model increases. In the example, the appearance probability in the case of 1 bit (=21) is calculated using the Softmax function, but for example, one output in the channel direction may be converted into a value between 0 and 1 using a Sigmoid function, and may be treated as the probability of outputting the symbol “1”. Then, the value obtained by subtracting the probability from 1 becomes the probability of outputting the symbol “0”.

As a method for learning the weights of neural networks in the estimation model processing and the mixer model processing, in the above description, the estimation model processing and the mixer model processing are configured with differentiable processing. Therefore, by calculating the relative entropy (or negative log likelihood, and the like) using the appearance probability of each symbol finally output by the mixer model and the training data (for example, a value corresponding to the appearance probability of each symbol expressed in one-hot format), and by learning the model end-to-end using an error backpropagation method or the like to minimize the value, the estimation accuracy may be improved. As for the timing of the learning, the learning may be carried out along the progress of the estimation processing in units of data as shown in FIGS. 8 and 9, or a model in a pre-trained state may be used. As in the overall learning processing (S12), the estimation model and the mixer model may be learned periodically based on data accumulated in the memory 52B, the memory 63B, the persistent storage device 54B, and the like of the computer 101B. Then, the learned model is saved in the persistent storage device 54B and the like, and the correspondence between the model and the data compressed by the model is recorded together with the compressed data 120a of the block data storage information 120 (model information 120d) to make restoration possible. By differentiating the model to be used based on identification information (code) representing the characteristics of the data, a dedicated learned model may be prepared for similar data to improve compression efficiency.

Next, an algorithm of the estimation model processing in the computer 101B will be described.

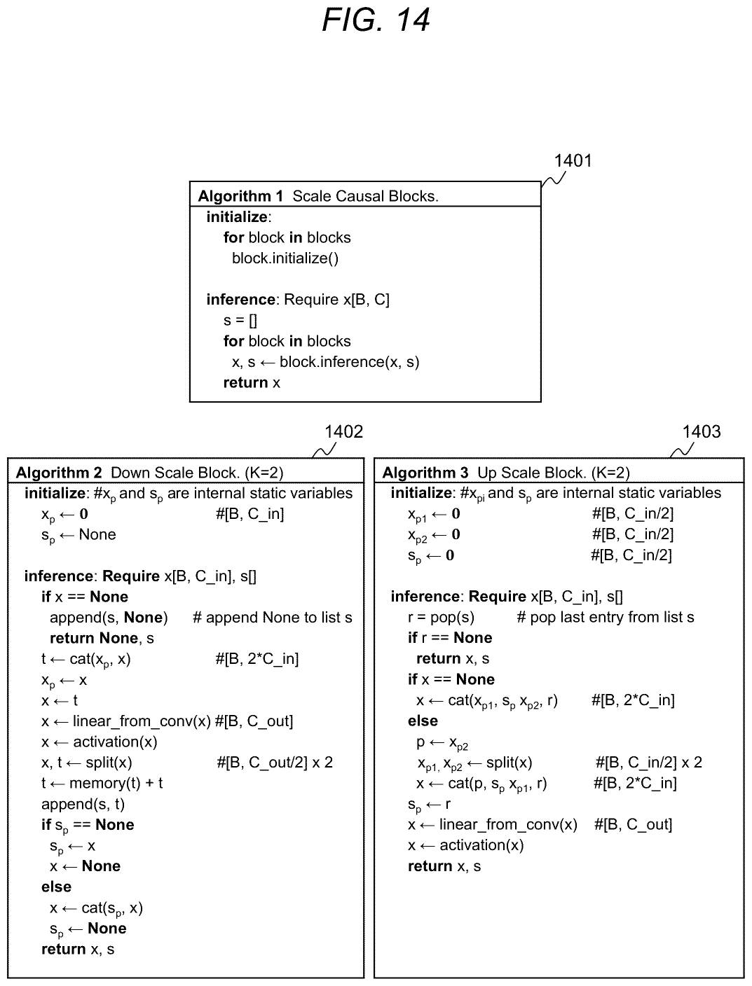

FIG. 14 is a diagram for describing the algorithm of the estimation model processing according to the first embodiment.

In FIG. 12, components of the SCB (downscale block, upscale block, and the like) that configure the estimation model were described. In the description of the module in FIG. 12, a convolution kernel is used as a neural network, and learning processing by is generally performed parallelizing (dividing and processing data for each kernel size) in the length (N) direction. Then, since a large number of data are input to the neural network in the length (N) direction, the multiplicity in the batch (B) direction is set to be relatively small (for example, 16 pieces). This is a suitable processing method in the overall learning processing (S12) in the compression processing. However, when operating as inference processing such as estimation model processing (S13 and S23), the batch multiplicity must be set higher (for example, several thousand or more) because the processing is iteration processing in symbol units. Therefore, as described in FIG. 13, by using a cache of intermediate data output from each component and by partially proceeding the computation processing in the length (N) direction, it is possible to improve memory usage efficiency and increase the degree of multiplicity in the batch (B) direction to various levels (for example, several thousand or more). Hereinafter, the inference processing will be specifically shown and described as an algorithmic procedure in FIG. 14.

First, an overall SCB algorithm 1401 mainly includes initialization processing (initialize in the drawing) and inference processing (inference in the drawing). Initialization processing is processing executed only at the initial execution when executing the estimation model processing (S13 and S23) on the processing target data (B*C*N array) obtained by dividing compression target data into the plurality of pieces of partial data. The inference processing is processing that takes one piece of processing target data in the length (N) direction (expressed by x in the drawing, B*C array) as an input, and is executed every iteration (executed N times) as the estimation model processing (S13 and S23). Note that the notation [X, Y] in the drawing represents the shape of an X*Y array (tensor), and [ ] represents an empty list structure. In the initialization processing, the initialization processing is executed for each component (block in the drawing) in the overall component configuration of the SCB (the one which is expressed as blocks in the drawing, and in which each component such as DB1, DB2, UB2, and UB1 is listed in the order of processing). In the inference processing, as shown in the algorithm 1401 in the drawing, the inference processing is executed for each component in order.

Next, a downscale block algorithm 1402 will be described. In the drawing, an algorithm for the case of kernel size K=2 is described as an example. Mainly, there are initialization processing (initialize in the drawing) and inference processing (inference in the drawing). In the initialization processing, initial values are respectively set for variables (xₚ and sₚ) used as two types of cache. Note that “0” in boldface in the drawing represents an array initialized with zero. The inference processing takes, as an input, an array (x) of the processing target data of B*C_in and a list (s) of arrays of data to be input to each subsequent upscale block, and outputs an array of B*C_out (the values of C_in and C_out may be different for each component). The basic operation of the inference processing is as shown in the algorithm described in FIG. 14, and the overview of the operation was already described in FIG. 13, and thus the details will be omitted, but only the characteristic parts of the inference processing will be described below. linear_from_conv in the drawing is processing in which the convolution processing described in FIG. 12 is replaced with a fully connected layer. Specifically, in the convolution processing, a fully connected layer can be regarded with K*C_in as an input and C_out as an output, and thus the processing is executed after converting the convolution kernel parameters into parameters of the fully connected layer. As a result, processing such as intermediate dimension conversion of arrays can be omitted and processing can be performed at high speed. As shown in the algorithm 1402, memory model processing (memory in the drawing) may be executed.

Next, an upscale block algorithm 1403 will be described. In the drawing, an algorithm for the case of kernel size K=2 is described as an example. Mainly, there are initialization processing (initialize in the drawing) and inference processing (inference in the drawing). In the initialization processing, initial values are respectively set for variables (Xₚ₁, Xₚ₂, and Sₚ) used as two types of cache. The inference processing takes, as an input, an array (x) of the processing target data of B*C_in and a list (s) of arrays of data input to each upscale block, and outputs an array of B*C_out.

As described above, by using the cache of intermediate data output by each component, and by proceeding the computation processing partially in the length (N) direction (processing in B*C array units), it is possible to improve memory usage efficiency, increase the degree of multiplicity in the batch (B) direction in stages (for example, several thousand or more), enabling high-speed processing.

Next, the processing operation of the estimation model processing using history information in the computer 101B will be described.

FIG. 15 is a diagram for describing the estimation model processing using history information according to the first embodiment.

The processing is an example of a method for implementing the estimation model 704a and the estimation model 714a (executed by the compression processing unit 702 and decompression processing unit 712) (simply referred to as an estimation model), in which a code is generated from input data, history information is generated using the code, and the estimation probabilities are generated based on the history information. The processing can be executed in parallel as threads for each dimension of the number of batches (B) operated on the core 62B of the parallel processing device 61B, for example.

The data input to the estimation model is an array of number of batches (B)*number of channels (C)*length of partial data (N), similar to FIG. 12. However, in the drawing, the dimension of the number of batches (B) will be omitted in description, the horizontal axis represents the length of the partial data (N), the channel has two types of axes, the vertical axis represents the number of symbols of the partial data (D=2^{u}), and the depth represents the code length (H). At the time of input, there is no code length (H) axis, and thus the length (H) is set to 1.

Note that during estimation model learning and compression, all pieces of compression target data are stored, and thus the plurality of pieces of estimation target data (N direction) can be processed collectively in parallel after matching the causal relationships of the data (for example, corresponding to the overall learning processing (S12) in FIG. 8). The description of FIG. 15 is for the case where the processing are collectively performed. Even in the case of parallelization in the batch direction (for example, corresponding to the estimation model processing (S13, S23)), as described in FIG. 14, by appropriately caching past computation data in the length (N) direction, the processing can be implemented as a high-speed iteration processing.

First, in the estimation model processing, input data shift processing is executed (S151). The input data shift processing is processing in which one padding is performed at the head of the input data in the length (N) direction, and one padding is deleted from the rear end. By the processing, the input data is moved by one piece to the past in the length (N) direction, and accordingly, the subsequent processing is processing of estimating the next input data from the past data.

Next, for input data 1501 as a result of S151, K pieces of padding are performed at the head in the length (N) direction (S152), and then a convolutional neural network (Convolution in the drawing) is processed (S153), and the Softmax function is processed in the code length (H) direction (S154), to obtain a code 1502. In the example, since the length (N) direction is one-dimensional, a one-dimensional convolutional neural network is applied. Note that the number of input channels of the convolutional neural network is D, the number of output channels is H, the kernel size is K (for example, K=256), and the stride width is 1. As a result, the size of the code 1502 is B*1*H*N+1. In the example, one convolutional neural network is used, but a multi-layered configuration may be used. Then, padding processing is appropriately performed in S152 considering the size of the receptive field in the multilayer network.

Next, the product of the input data 1501 (size B*D*1*N) and the code 1502 for each element is computed (S155). Here, N elements (size B*1*H*N) are acquired from the head of the code 1502 in the length (N) direction and used for computing the product. This corresponds to the past value of the code 1502. When computing the product for each element, dimension expansion (copying) is performed for dimensions with one element to match the numbers for each of the product arithmetic operation targets. Therefore, the size of the result of S155 is B*D*H*N. A tensor (size B*D*H*N) is computed by cumulatively adding resulting tensors in the length (N) direction (Cumsum in the drawing) (S156). The result is defined as history information 1503. The history information 1503 can be considered to represent a temporal evolution (dimension: N) of the appearance frequency of each symbol (dimension: D) corresponding to each code (dimension: H).

Next, the product of the history information 1503 and each element of the code 1502 is computed (S157). Here, N elements (size B*1*H*N) are acquired from the second from the head of the code 1502 in the length (N) direction and used for computing the product. This corresponds to the current value of the code 1502. When computing the product for each element, dimension expansion (copying) is performed for dimensions with one element to match the numbers for each of the product arithmetic operation targets. Therefore, the size of the result of S157 is B*D*H*N. Next, the result of summing the resulting tensor in the code length (H) direction is output (the size is B*D*1*N) (S158). Next, normalization processing is performed such that the total value becomes 1 in dimension D (S159). For example, the computation is performed by computing a value by adding a small value E to the total value of dimension D so as not to become zero, and dividing the elements of each value of dimension D by the value. As a result, a tensor of size B*D*1*N can be obtained as an estimated probability 1504. The dimension in the length (H) direction of the code is 1, which is the same as the input data, and can be ignored, and is input to the mixer model as a tensor representing the estimated probability of size B*D*N.

Note that, in the case of a value generated by the convolutional neural network (S153) using random numbers, the value can also be considered to be LSH. Therefore, in the method shown in the example, since the random numbers are used as initial values for learning, a learning type LSH is positioned as it is, and through learning, it is possible to generate estimated probabilities more efficiently and with higher accuracy than LSH. In the example, the code for each data unit is expressed by a discrete vector with H elements totaling 1, but the code is expressed by a continuous probability density function such as Gaussian distribution, and the estimated probability 1504 may be computed. For example, when expressing a code using Gaussian distribution, the code can be expressed by a vector with two elements for average and variance.

Next, the processing operation of the memory model processing using history information in the computer 101B will be described.

FIG. 16 is a diagram for describing the memory model processing using the history information according to the first embodiment.

The processing is processing corresponding to the memory model in downscale block S122 in FIG. 12. Since the processing includes many parts that overlap with the estimation model processing using history information described with reference to FIG. 15, the parts that do not overlap will be mainly described.

In the processing, input data 1601 is padded (S161), convolution processing (S162, setting example of convolution is K=1, input channel=C, and output channel=Cv) is executed, and then the Softmax function is executed on the channel dimension (S163) to obtain value data 1602. The subsequent processing (S164 to S1610) are basically the same as the processing (S152 to S159) described in FIG. 15. As the next processing, convolution processing (S1611, setting example of convolution is K=1, input channel=Cv, and output channel=C) is executed to obtain output data 1605.

By storing history information in the length (N) direction as described above, probability estimation accuracy can be improved. The dimension of Cv of the value data and H of the code may be each divided into predetermined numbers to perform the subsequent processing. By the division, the memory amount and computation amount of history information can be efficiently reduced.

Next, the processing operation of the memory model processing using exponential moving average in the computer 101B will be described.

FIG. 17 is a diagram for describing memory model processing using the exponential moving average according to the first embodiment.

The processing is processing corresponding to the memory model in the downscale block S122 of FIG. 12, and may be implemented instead of the memory model processing using history information described in FIG. 16, or both may be implemented in parallel or in series.

Input information 1701 input to the memory model is an array of number of batches (B)*number of channels (C)*length of partial data (N), but in the drawing, the dimension of number of batches (B) will be omitted in description.

Note that during estimation model learning and compression, all pieces of compression target data are stored, and thus the plurality of pieces of estimation target data (N direction) can be processed collectively in parallel after matching the causal relationships of the data (for example, corresponding to the overall learning processing (S12) in FIG. 8). The description of FIG. 17 is for the case where the processing are collectively performed. In the processing, even in the case of parallelization in the batch direction (for example, corresponding to the estimation model processing (S13, S23)), as described in FIG. 14, by storing the latest exponential moving average result and using the result for the next computation in the iterations in the length (N) direction, it is possible to implement high-speed, highly multiplexed iteration processing.

In the processing, convolution processing (S171, setting example of convolution is K=1, input channel=C, and output channel=Ce) is executed on the input information 1701 to obtain intermediate information 1702.

Next, the exponential moving average in the length (N) dimension direction is calculated for the intermediate information (M_{1 to N}) 1702 using the parameter α for each channel dimension Ce (S172), and exponential moving average information 1703 is obtained. Specifically, each exponential moving average (E_{1 to N}) in the length (N) dimension direction will be given by the following equation.

$${E}_{i} = ( 1 - α ) * {E}_{i - 1} + α ⋆ {M}_{i}$$

Here, i is 1 to N, and Eₒ is a matrix initialized to zero, for example. The arithmetic operation * is an element-wise product arithmetic operation that expands dimensions other than the channel dimension. The parameter α can be a learning target parameter (differentiable) during learning of the estimation model, and as an effect thereof, an efficient exponential moving average parameter can be determined by learning from data.

Next, the convolution processing (S173, setting example of convolution is K=1, input channel=Ce, and output channel=C) is executed on the exponential moving average information 1703 to obtain output information 1704.

As described above, by slightly additional computation processing of the memory model, the receptive field of the entire neural network that configures the estimation model can be widened in the entire length (N) direction regardless of the number of layers or kernel size, and it is possible to efficiently improve probability estimation accuracy.

Next, a computer system according to a modification example will be described.

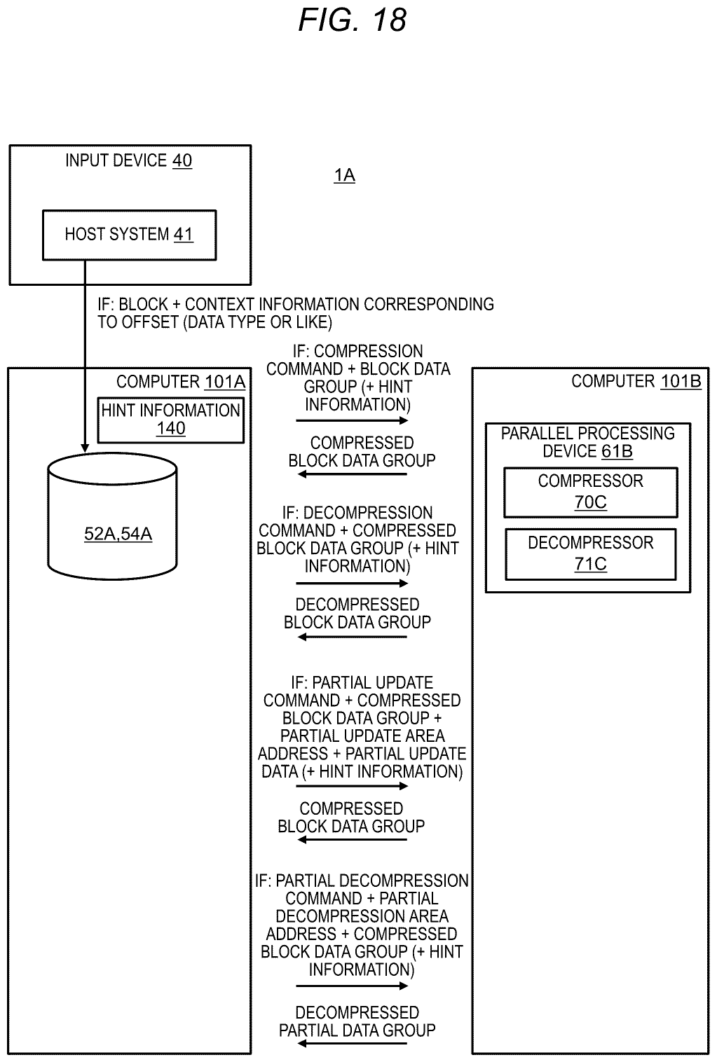

FIG. 18 is a diagram illustrating the computer system according to the modification example.

In a computer system 1A according to the modification example, the input device 40 operates a host system 41 that processes data stored in the computer 101A. The host system 41 is, for example, a file system, an object system, a database system, a web application, or the like. The host system 41 transmits a plurality of pieces of storage target block data (block data group) to the computer 101A. Here, the host system 41 includes a block data group (or reference information thereof), a command identification code (for example, write, read, discard, and the like), and hint information related to compression of the block data as optional information, and transmits the block data group to the computer 101A. Here, the hint information includes the data type of the block data, information indicating context switching in the block data, and the like.

The processor 53A of the computer 101A stores the block data group received from the input device 40 in the memory 52A or the persistent storage device 54A, and when there is hint information 140 corresponding to the block data group, the processor 53A stores the hint information 140 in the memory 52A or the persistent storage device 54A. Here, the functional unit in which the processor 53A executes the above processing corresponds to a reception unit.

Next, when executing processing related to compression and decompression for the block data group, the computer 101A transmits a command to the computer 102A using IF, including the block data group (or the reference information thereof), a command identification code (for example, a code that identifies four types such as compression, decompression, partial update, and partial decompression), information on addresses, and hint information related to compression of the block data as optional information.

When the computer 101A compresses the block data group, the computer 101A adds the compression target block data group (or the reference information thereof) and optional hint information to the compression command, and transmits the command to the computer 101B. In the computer 101B, a compressor 70C configured with the parallel processing device 61B compresses a block data group (when the hint information is designated, compresses based on the hint information), and transmits the compressed block data group (a set of the corresponding block data storage information 120 or the reference information thereof) to the computer 101A. For example, the compressor 70C is configured such that the hint information is further input to the estimation model 704a and/or the mixer model 704b in the compressor 70B, and the appearance probability is calculated based on the hint information.

When the computer 101A decompresses the compressed block data group, the computer 101A adds the compressed block data group (or the reference information thereof) and optional hint information to the decompression command, and transmits the command to the computer 101B. In the computer 101B, the decompressor 71C configured with the parallel processing device 61B decompresses the block data group based on the hint information (when the hint information is designated, decompresses based on the hint information), and transmits the decompressed block data group (or the reference information thereof) to the computer 101B. For example, the decompressor 71C is configured such that the hint information is further input to the estimation model 714a and/or the mixer model 714b in the decompressor 71B, and the appearance probability is calculated based on the hint information.

When partially updating the compressed block data group, the computer 101A adds the compressed block data group (or the reference information thereof), address information representing an area to be partially updated, data to be partially updated, and optional hint information to the partial update command, and transmits the partial update command to the computer 101B. In the computer 101B, the compressor 70C configured with the parallel processing device 61B compresses only the partial update data (partial data) corresponding to the partial update area address (when the hint information is designated, compresses based on the hint information), updates the compressed data 120a, the guarantee code 120b, and the compressed size 120c of the block data storage information 120 corresponding to the partial update area address, and transmits the compressed block data group (the corresponding set of the block data storage information 120 or the reference information thereof) to the computer 101A. In the partial update processing, execution of the overall learning processing (S12) in the compression processing is not necessary. As described above, it is possible to perform partial updates in units of partial data (for example, 1 KB) while using an estimation model that is fully learned based on data trends with large block sizes (for example, several MB to several GB), it is not necessary to decompress and recompress the entire data, and thus the processing efficiency of partial updates can be improved.

When partially decompressing the compressed block data group, the computer 101A adds the compressed block data group (or the reference information thereof), address information representing an area to be partially decompressed, and optional hint information to the partial decompression command, and transmits the partial decompression command to the computer 101B. In the computer 101B, the decompressor 71C configured with the parallel processing device 61B decompresses the partial data group corresponding to the address information representing an area to be partially decompressed (when the hint information is designated, decompresses based on the hint information), and the decompressed partial data group (or the reference information thereof) is transmitted to the computer 101B. As described above, processing efficiency can be improved by decompressing only the necessary parts.

In the above configuration, the computer 101B may store the block data storage information 120 and the address mapping table 110 in the memory 52B, the memory 63B, or the persistent storage device 54B. Then, the pre-coding unit 703 computes the hash value of the partial compression target data and compares the hash values to detect overlap with previously processed partial data. Regarding the overlapping data, only reference information to previously processed partial data is saved in the address mapping table 110 or the block data storage information 120, and when increasing the compression ratio (when performing overlap removal), in the above-described IF (compression command, partial update command), instead of outputting the compressed data itself, only the reference information to the previously processed partial data is output.

In the above configuration, the computer 101A and the computer 101B can securely communicate and store data by encrypting the transmitted and received IF contents.

According to the computer system 1A, the computer 101A can use the IF to execute compression/decompression processing using the computing resources of the computer 101B, and thus various other processing (storage control program and the like) that should be executed by the computer 101A can be performed without consuming computing resources by the compression/decompression processing. Particularly in an environment such as a cloud, a low-cost computer environment that does not include the parallel processing device 61 required to achieve efficient compression can be used as the computer 101A, and thus it is possible to reduce the cost of the entire system. Since the hint information is used to calculate the appearance probability of each data unit, the appearance probability can be calculated with higher accuracy and the compression efficiency can be improved.

Next, a computer system according to a second embodiment will be described. The computer system according to the second embodiment is a computer system that performs lossy compression and decompression with respect to media data such as videos, still images, and point clouds. The computer system according to the second embodiment includes a compressor 74 (74A, 74B) (refer to FIG. 16) instead of the compressor 70 (70A, 70B) in the computer system 1 according to the first embodiment, and a decompressor 75 (75A, 75B) (refer to FIG. 17) instead of the decompressor 71 (71A, 71B).

Next, the configuration and processing of the compressor 74 (74A, 74B) will be described.

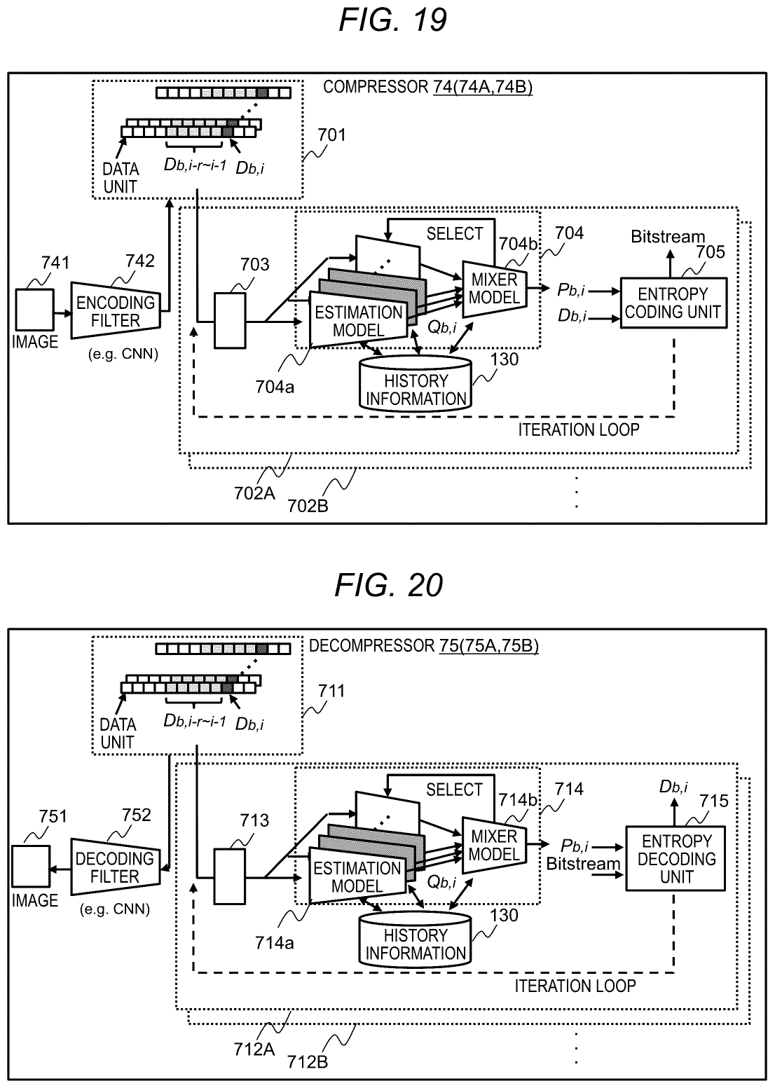

FIG. 19 is a diagram for describing a compressor of the computer system according to the second embodiment.

The compressor 74 (74A, 74B) further includes an encoding filter 742 compared to the compressor 70 (70A, 70B). The encoding filter 742 is, for example, an example of a data reduction unit, and performs processing to reduce the data volume on image data 741, and outputs data after data reduction (compression target data after data reduction). For example, the encoding filter 742 may be configured with convolutional neural networks (CNN).

According to the configuration, the data used for input to the plurality of probability calculation units 704 is an array of the number of height pixels (H)*the number of width pixels (W)*the number of channels (C: in the case of an image, for example, 3 of RGB)*number of batches (B).

Next, the configuration and processing of the decompressor 75 (75A, 75B) will be described.

FIG. 20 is a diagram for describing a decompressor of the computer system according to the second embodiment.

The decompressor 75 (75A, 75B) is different from the decompressor 71 (71A, 71B) in that a decoding filter 752 that generates an image 751 from the decompressed data is further provided. The decoding filter 752 increases the data volume and generates the image 751 that is substantially similar to the original image 741. The decoding filter 752 may be configured with CNN, for example.

According to the configuration, the data output from the plurality of decompression processing unit 712 is an array of the number of height pixels (H)*the number of width pixels (W)*the number of channels (C: in the case of an image, for example, 3 of RGB)*number of batches (B).

Note that in the above example, a still image was taken as an example of media data, but for example, in the case of a video, data used for input to the plurality of probability calculation units 704 may be a five-dimensional tensor obtained by adding a time component to the tensor for a still image.

The present invention is not limited to the above-described embodiments, and can be appropriately modified and carried out without departing from the spirit of the present invention.

For example, in the above embodiment, the parallel processing device is different from the processor 53 (53A, 53B), but when the processor 53 includes a plurality of cores, the processor 53 may be used as the parallel processing device.

In the above-described embodiments, a part or all of the processing performed by the processor may be performed by a hardware circuit. The programs in the above-described embodiments may be installed from a program source. The program source may be a program distribution server or a recording medium (for example, a portable recording medium).

1. A data compression system that compresses data, the system comprising:
a division unit that divides compression target data into a plurality of pieces of partial data; and
a plurality of compression processing units that perform compression processing on each piece of the partial data in parallel, wherein
the compression processing unit includes
a probability calculation unit that includes a neural network and calculates an appearance probability for each predetermined data unit of the partial data, and
an entropy coding unit that outputs a coded bit string that is an entropy-coded bit string based on the data unit and the appearance probability for each data unit.

2. The data compression system according to claim 1, wherein
the probability calculation unit includes an estimation model that calculates estimation information for each data unit, and the estimation model is configured with a neural network.

3. The data compression system according to claim 2, wherein
the estimation model is configured with a neural network including processing of reducing a length direction.

4. The data compression system according to claim 1, wherein
the probability calculation unit is configured with a plurality of estimation models that calculate estimation information for each data unit, and includes a mixer model that determines an appearance probability of each data unit based on estimation information output by the plurality of estimation models.

5. The data compression system according to claim 4, wherein
the mixer model includes weights for outputs from a plurality of estimation models,
the data compression system further comprises:
a learning unit that determines weights for the estimation model by performing learning processing on the mixer model; and
a model selection unit that selects an estimation model to be used by the probability calculation unit based on the weights.

6. The data compression system according to claim 1, further comprising:
a history management unit that stores history information in a storage unit, the history information including identification information for identifying data used during calculation which is data used to calculate an appearance probability of the data unit and the calculated appearance probability, wherein
the probability calculation unit calculates an appearance probability based on the history information.

7. The data compression system according to claim 6, wherein
the history management unit calculates locality sensitive hashing (LSH) corresponding to the data used during calculation as the identification information.

8. The data compression system according to claim 1, wherein
the compression processing unit includes a conversion unit that inputs a bit string to the probability calculation unit, the bit string being obtained by performing one-hot encoding on each data unit of compression target data.

9. The data compression system according to claim 1, further comprising:
a reception unit that receives a command identification code and data related to compression of the compression target data, wherein
the compression processing unit compresses data based on the command identification code and data.

10. The data compression system according to claim 9, further comprising:
a reception unit that receives hint information related to compression of the compression target data, wherein
the probability calculation unit calculates a probability distribution for each data unit based on the hint information.

11. The data compression system according to claim 1, further comprising:
a storage processing unit that stores coded bit strings corresponding to a plurality of pieces of the partial data such that the coded bit strings corresponding to each piece of partial data are identifiable.

12. The data compression system according to claim 11, wherein
in the compression processing unit,
regarding a coded bit string corresponding to a part of each piece of partial data,
the probability calculation unit calculates an appearance probability for each predetermined data unit of each piece of partial data only for update data corresponding to a part of each piece of partial data, and outputs a coded bit string by the entropy coding unit.

13. The data compression system according to claim 1, wherein
the compression target data is predetermined media data,
the data compression system further comprises a data reduction unit that reduces data volume of the compression target data, and
the division unit divides the compression target data after data reduction in which the data volume is reduced by the data reduction unit.

14. The data compression system according to claim 1, further comprising:
a plurality of decompression processing units that perform decompression processing on each coded bit string corresponding to the plurality of pieces of partial data, and
the decompression processing unit includes
a second probability calculation unit that includes a neural network and calculates an appearance probability for each predetermined data unit of the partial data, and
an entropy decoding unit that outputs an entropy-decoded data unit based on the coded bit string and the appearance probability.

15. The data compression system according to claim 1, further comprising:
a decompression unit that decompresses first compressed data which is compressed in block units of a predetermined first size and is associated with a guarantee code in first block units of the first size, wherein
the division unit divides decompressed data decompressed by the decompression unit, and
the data compression system further comprises a second block corresponding guarantee code creation unit that creates a guarantee code in second block units of a second size with respect to the plurality of coded bit strings obtained by the compression processing unit, and stores the guarantee code in association with a second block corresponding bit string group which is a coded bit string corresponding to the second block unit.

16. The data compression system according to claim 15, further comprising:
a plurality of decompression processing units that perform decompression processing in parallel on coded bit strings corresponding to the plurality of pieces of partial data in the second block corresponding bit string group, wherein
the decompression processing unit includes
a second probability calculation unit that includes a neural network and calculates an appearance probability for each predetermined data unit of the partial data,
an entropy decoding unit that outputs an entropy-decoded data unit based on the coded bit string and the appearance probability, and
a first block corresponding guarantee code creation unit that creates a guarantee code for each first block unit based on a plurality of data units included in the first block unit of the first size.

17. The data compression system according to claim 1, wherein
the compression processing unit uses reference information to the partial data as a compression result when overlap between previously processed partial data and the partial data is detected.

18. A data compression method performed by a data compression system that compresses data, the method comprising:
dividing compression target data into a plurality of pieces of partial data; and
performing compression processing on each piece of the partial data in parallel by a plurality of compression processing units, wherein
the compression processing unit
calculates an appearance probability for each predetermined data unit of the partial data using a neural network, and
outputs a coded bit string that is an entropy-coded bit string based on the data unit and the appearance probability for each data unit.

19. A non-transitory computer-readable medium including executable instructions stored in a memory, the executable instructions configured for data compression so as to execute processing of compressing data,
as the instructions comprising:
dividing compression target data into a plurality of pieces of partial data, and
in a plurality of compression processing units, performing compression processing on each piece of the partial data in parallel, and
the compression further comprising:
performing a probability calculation by a neural network and calculating an appearance probability for each predetermined data unit of the partial data, and
outputting a coded bit string that is an entropy-coded bit string based on the predetermined data unit of the partial data, and the appearance probability for each predetermined data unit of the partial data.
